(19) United States
(12) Patent Application Publication
(10) Pub. No.: US 2026/0314340 A1
(43) Pub. Date: Oct. 8, 2026

(54) METHOD FOR FORMING PATTERNED MASK ON SUBSTRATE

(71) Applicant: Tokyo Electron Limited, Tokyo (JP)

(72) Inventors: Michael Murphy, Niskayuna, NY (US); Jodi Grzeskowiak, Schenectady, NY (US)

(21) Appl. No.: 19/171,866

(22) Filed: Apr. 7, 2025

(51) Int. Cl. H01L 21/027; H01L 21/311

(52) U.S. Cl. CPC H10P 76/2043; H10P 50/73; H10P 76/202

(57) ABSTRACT

A method includes a process for forming a patterned mask. First mandrels formed on a substrate are covered with a first polymer. Acid generated in the first polymer diffuses into the first mandrels, creating deprotected regions. After removing the first polymer, a second polymer is applied and partially removed to expose the deprotected first mandrel regions. Remaining portions of the second polymer form second mandrels. The deprotected first mandrel regions are selectively removed, leaving protected regions of the first mandrels as third mandrels. A third polymer is applied over both second and third mandrels. Additional acid generated in the third polymer diffuses into the second and third mandrels, creating deprotected regions. After partial removal of the third polymer, the exposed deprotected regions of the second and third mandrels are selectively removed. Remaining portions of the third polymer and the protected regions of second and third mandrels form the patterned mask.

### TECHNICAL FIELD

The present disclosure relates generally to methods for processing a substrate, and, in particular embodiments, to methods for forming a patterned mask on a substrate.

### BACKGROUND

Generally, a semiconductor device, such as an integrated circuit (IC) is fabricated by sequentially depositing and patterning layers of dielectric, conductive, and semiconductor materials over a semiconductor substrate to form a network of electronic components and interconnect elements (e.g., transistors, resistors, capacitors, metal lines, contacts, and vias) integrated in a monolithic structure. At each successive technology node, the minimum feature sizes are shrunk to reduce cost by roughly doubling the component packing density.

Photolithography is a common patterning method in semiconductor fabrication. A photolithography process may start by exposing a coating of photoresist comprising a radiation-sensitive material to a pattern of actinic radiation to define a relief pattern. For example, in the case of positive photoresist, irradiated portions of the photoresist may be dissolved and removed by a developing step using a developing solvent, forming the relief pattern of the photoresist. The relief pattern then may be transferred to a target layer below the photoresist or an underlying hard mask layer formed over the target layer. Innovations on photolithographic techniques may be needed to satisfy the cost and quality requirements for patterning of nanoscale features.

### SUMMARY

In accordance with an embodiment of the present disclosure, a method includes forming first mandrels over a substrate and forming a first polymer layer over the first mandrels. A top surface of the first polymer layer is above top surfaces of the first mandrels. The method further includes generating first free acid in the first polymer layer and diffusing the first free acid into the first mandrels to form deprotected regions of the first mandrels. Remaining portions of the first mandrels form protected regions of the first mandrels. The method further includes selectively removing the first polymer layer and forming a second polymer layer over the first mandrels. A top surface of the second polymer layer is above top surfaces of the first mandrels. The method further includes removing a portion of the second polymer layer to expose the deprotected regions of the first mandrels. Remaining portions of the second polymer layer form second mandrels. The method further includes selectively removing the deprotected regions of the first mandrels. The protected regions of the first mandrels form third mandrels. The method further includes forming a third polymer layer over the second mandrels and the third mandrels. A top surface of the third polymer layer is above top surfaces of the second mandrels and the third mandrels. The method further includes generating second free acid in the third polymer layer and diffusing the second free acid into the second mandrels to form deprotected regions of the second mandrels. Remaining portions of the second mandrels form protected regions of the second mandrels. The method further includes diffusing the second free acid into the third mandrels to form deprotected regions of the third mandrels. Remaining portions of the third mandrels form protected regions of the third mandrels. The method further includes removing a portion of the third polymer layer to expose the deprotected regions of the second mandrels and the deprotected regions of the third mandrels. Remaining portions of the third polymer layer form fourth mandrels. The method further includes selectively removing the deprotected regions of the second mandrels and the deprotected regions of the third mandrels. The protected regions of the second mandrels, the protected regions of the third mandrels, and the fourth mandrels form a patterned mask.

In accordance with another embodiment of the present disclosure, a method includes forming first mandrels over a substrate and forming a first polymer layer over the first mandrels. A top surface of the first polymer layer is above top surfaces of the first mandrels; generating first free acid in the first polymer layer. The method further includes diffusing the first free acid into the first mandrels to form deprotected regions of the first mandrels. Remaining portions of the first mandrels form protected regions of the first mandrels. The method further includes selectively removing the first polymer layer and forming a second polymer layer over the first mandrels. A top surface of the second polymer layer is above top surfaces of the first mandrels. The method further includes removing a portion of the second polymer layer to expose the deprotected regions of the first mandrels. Remaining portions of the second polymer layer form second mandrels. The method further includes selectively removing the deprotected regions of the first mandrels. The protected regions of the first mandrels form third mandrels. The method further includes forming a third polymer layer over the second mandrels and the third mandrels. A top surface of the third polymer layer is above top surfaces of the second mandrels and the third mandrels. The method further includes generating second free acid in the second mandrels and third free acid in the third mandrels, diffusing the second free acid into the third polymer layer to form first deprotected regions of the third polymer layer, and diffusing the third free acid into the third polymer layer to form second deprotected regions of the third polymer layer. A remaining portion of the third polymer layer forms a protected region of the third polymer layer. The method further includes removing a portion of the protected region of the third polymer layer to expose the first deprotected regions and the second deprotected regions of the third polymer layer. Remaining portions of the protected region of the third polymer layer form fourth mandrels. The method further includes selectively removing the first deprotected regions and the second deprotected regions of the third polymer layer. The second mandrels, the third mandrels, and the fourth mandrels form a patterned mask.

In accordance with yet another embodiment of the present disclosure, a method includes forming first mandrels over a substrate and forming a first polymer layer over the first mandrels. A top surface of the first polymer layer is above top surfaces of the first mandrels. The method further includes generating first free acid in the first mandrels and diffusing the first free acid into the first polymer layer to form deprotected regions of the first polymer layer. A remaining portion of the first polymer layer forms a protected region of the first polymer layer. The method further includes removing a portion of the protected region of the first polymer layer to exposed the deprotected regions of the first polymer layer. Remaining portions of the protected region of the first polymer layer form second mandrels. The method further includes selectively removing the protected regions of the first polymer layer and forming a second polymer layer over the first mandrels and the second mandrels. A top surface of the second polymer layer is above top surfaces of the first mandrels and the second mandrels. The method further includes generating second free acid in the second polymer layer and diffusing the second free acid into the first mandrels to form deprotected regions of the first mandrels. Remaining portions of the first mandrels form protected regions of the first mandrels. The method further includes diffusing the second free acid into the second mandrels to form deprotected regions of the second mandrels. Remaining portions of the second mandrels form protected regions of the second mandrels. The method further includes removing a portion of the second polymer layer to expose the deprotected regions of the first mandrels and the deprotected regions of the second mandrels. Remaining portions of the second polymer layer form third mandrels. The method further includes selectively removing the deprotected regions of the first mandrels and the deprotected regions of the second mandrels. The protected regions of the first mandrels, the protected regions of the second mandrels, and the third mandrels form a patterned mask.

### BRIEF DESCRIPTION OF THE DRAWINGS

For a more complete understanding of the present disclosure, and the advantages thereof, reference is now made to the following descriptions taken in conjunction with the accompanying drawings, in which:

FIGS. 1A-1J illustrate cross-sectional views of intermediate stages in the manufacturing of a patterned mask over a substrate in accordance with various embodiments;

FIGS. 2A-2E illustrate cross-sectional views of intermediate stages in the manufacturing of a patterned mask over a substrate in accordance with various embodiments;

FIGS. 3A-3K illustrate cross-sectional views of intermediate stages in the manufacturing of a patterned mask over a substrate in accordance with various embodiments;

FIGS. 4A-4H illustrate cross-sectional views of intermediate stages in the manufacturing of a patterned mask over a substrate in accordance with various embodiments;

FIGS. 5A-5E illustrate cross-sectional views of intermediate stages in the manufacturing of a patterned mask over a substrate in accordance with various embodiments;

FIGS. 6A-6K illustrate cross-sectional views of intermediate stages in the manufacturing of a patterned mask over a substrate in accordance with various embodiments;

FIGS. 7A and 7B illustrate a flow diagram of a method for forming a patterned mask over a substrate in accordance with various embodiments;

FIG. 8 illustrates a flow diagram of a method for forming a patterned mask over a substrate in accordance with various embodiments;

FIG. 9 illustrates a flow diagram of a method for forming a patterned mask over a substrate in accordance with various embodiments;

FIGS. 10A and 10B illustrate a flow diagram of a method for forming a patterned mask over a substrate in accordance with various embodiments;

FIG. 11 illustrates a flow diagram of a method for forming a patterned mask over a substrate in accordance with various embodiments; and

FIGS. 12A and 12B illustrate a flow diagram of a method for forming a patterned mask over a substrate in accordance with various embodiments.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

The present disclosure provides a method for forming a patterned mask over a substrate. In an embodiment, the method includes forming mandrels over a substrate and using a series of polymer layers and acid diffusion steps to progressively refine the pattern. Free acid is generated in polymer layers and diffused into adjacent mandrels or other polymer layers to create deprotected regions. Selective removal of the deprotected regions and portions of polymer layers results in the formation of additional mandrels. This process may be repeated with multiple polymer layers and acid diffusion steps to create a final patterned mask with refined feature sizes.

Various embodiments of the present disclosure offer several advantages. Various embodiments provide control over feature dimensions, enabling the creation of patterns with sizes below the limits of conventional lithography techniques. The use of multiple polymer layers and controlled acid diffusion processes allows for fine-tuning of pattern geometries and the creation of complex patterns. By controlling acid diffusion and selectively removing deprotected regions, the feature sizes can be progressively reduced in a controlled manner. This enables the fabrication of semiconductor devices with smaller feature sizes and higher component density. Various embodiments further provide flexibility in tuning the final pattern dimensions by adjusting parameters like acid concentrations, diffusion depths, radiation exposure conditions and/or thermal process conditions at each stage.

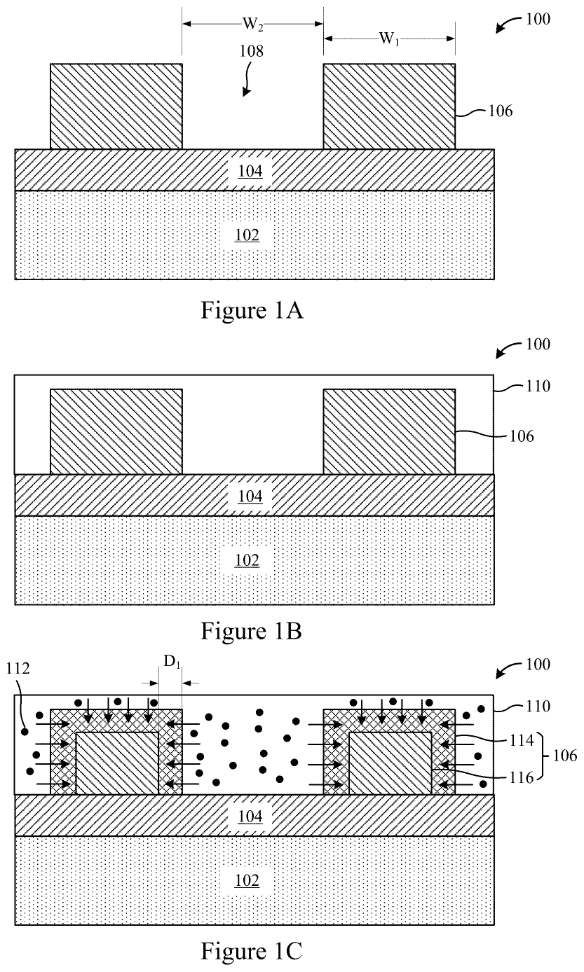

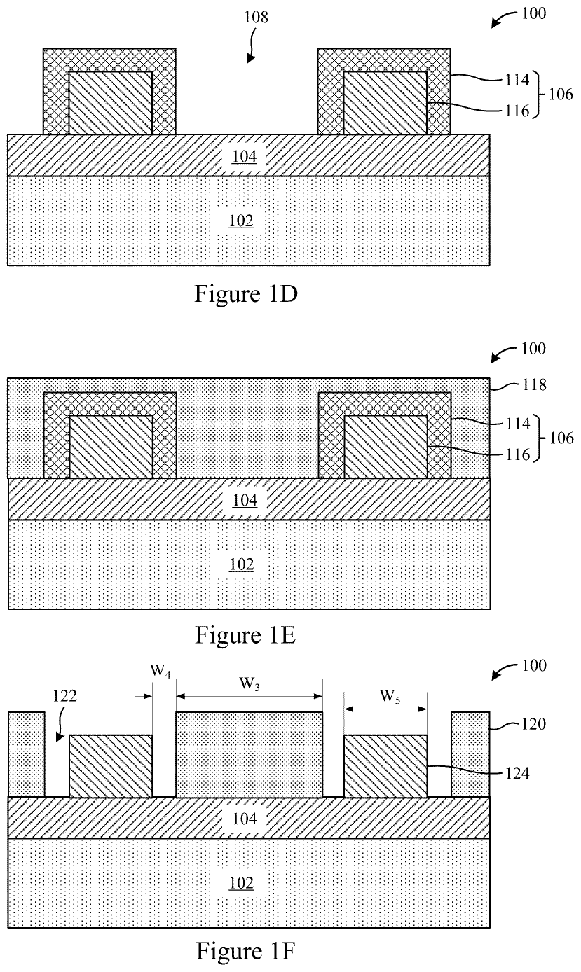

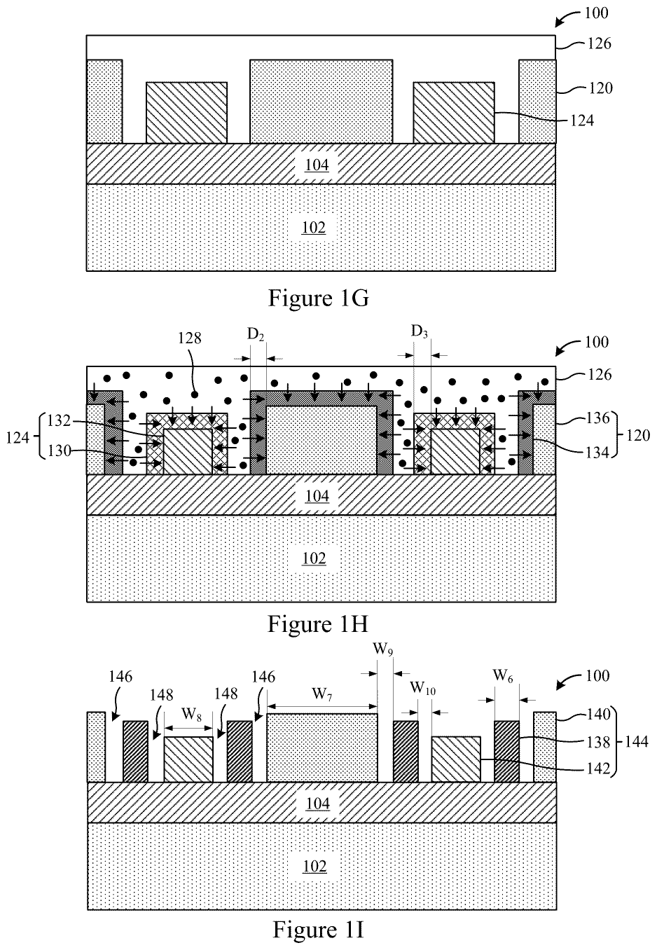

FIGS. 1A-1J illustrate cross-sectional views of intermediate stages in the manufacturing of a patterned mask over a substrate in accordance with various embodiments. In FIG. 1A, a semiconductor structure 100 is illustrated. The semiconductor structure 100 may include a substrate 102. The substrate 102 may comprise layers of semiconductors suitable for various microelectronics. In one or more embodiments, the substrate 102 may be a silicon wafer, or a silicon-on-insulator (SOI) wafer. In certain embodiments, the substrate 102 may comprise a silicon germanium wafer, silicon carbide wafer, gallium arsenide wafer, gallium nitride wafer, or other compound semiconductors. In other embodiments, the substrate 102 may comprise heterogeneous layers such as silicon germanium on silicon, gallium nitride on silicon, silicon carbon on silicon, or layers of silicon on a silicon or SOI substrate.

In some embodiments, the substrate 102 may further include semiconductor devices or semiconductor structures and may be formed in any suitable manner, including using any suitable combination of wet and/or dry deposition and etch techniques. In such embodiments, the substrate 102 may include isolation regions such as shallow trench isolation (STI) regions, diffusion regions, as well as other regions formed therein.

In some embodiments, a target layer 104 is formed over the substrate 102. The target layer 104 represents a layer that will be subsequently patterned. In one or more embodiments, the target layer 104 may comprise materials such as silicon, silicon oxynitride, organic materials, non-organic materials, or amorphous carbon. In an embodiment, the target layer 104 may be a silicon bottom anti-reflective coating (Si-BARC), which can enhance the precision of subsequent patterning steps. The target layer 104 may also serve as a mask layer, comprising either a single hard mask or a stacked hard mask. In the case of a stacked hard mask, it may consist of two or more layers of different materials. For instance, in a two-layer configuration, the first layer might comprise a metal-based material such as titanium nitride, titanium, tantalum nitride, tantalum, tungsten-based compounds, ruthenium-based compounds, or aluminum-based compounds. The second layer, in contrast, might be a dielectric layer composed of materials like silicon dioxide, silicon nitride, silicon oxynitride, silicon carbide, amorphous silicon, or polycrystalline silicon. In other embodiments, the target layer 104 may be a dielectric material, a conductive material, or a semiconductor material, depending on the specific application requirements.

The deposition of the target layer 104 may be achieved through various suitable processes. In some embodiments, the target layer 104 may be deposited using spin-on coating techniques, chemical vapor deposition (CVD), atomic layer deposition (ALD), plasma-enhanced CVD (PECVD), plasma-enhanced ALD (PEALD), a combination thereof, or the like. The choice of deposition method depends on factors such as the desired thickness, uniformity, and material properties of the target layer 104.

In some embodiments, mandrels 106 are formed over the target layer 104. The mandrels 106 may be separated by openings 108. The openings 108 define areas where the underlying target layer 104 is exposed. The mandrels 106 may have a width W₁ and the openings 108 may have a width W₂. The width W₁ may be same as or different from the width W₂. In some embodiments, the mandrels 106 may be formed by forming a photoresist layer (not shown) over the target layer 104 and patterning the photoresist layer using suitable photolithographic techniques. The photoresist layer may comprise a positive-tone photoresist or a negative-tone photoresist. The photoresist layer may be deposited on the target layer 104 in any suitable manner. In some embodiments, the photoresist layer may be deposited by spin-coating, spray-coating, dip-coating, roll-coating, CVD, ALD, a combination thereof, or other suitable processes.

In various embodiments, the photoresist layer may comprise an agent-generating ingredient that, in response to a suitable agent-activation trigger (e.g., heat or radiation), generates a solubility-changing agent (e.g., an acid). Example agent-generating ingredients may include a thermal-acid generator (TAG) that is configured to generate an acid in response to heat or a photo-acid generator (PAG) that is configured to generate an acid in response to actinic radiation.

After forming the photoresist layer, a reticle (not shown) is disposed over the photoresist layer. The reticle may be used to modulate a dose (or an intensity) of a radiation (e.g., actinic radiation) that is used to expose the photoresist layer. In such embodiments, the reticle may comprise regions of different transparency to the radiation (e.g., opaque and transparent regions). The photoresist layer is then subject to an exposure step through the reticle. The radiation exposes exposed regions of the photoresist layer while unexposed (or unmodified) regions of the photoresist layer are protected by the reticle. The exposure step may be performed using a photolithographic technique such as dry lithography (e.g., using 193 dry lithography), immersion lithography (e.g., using 193 nanometer immersion lithography), i-line lithography (e.g., using 365 nanometer wavelength UV radiation for exposure), H-line lithography (e.g., using 405 nanometer wavelength UV radiation for exposure), extreme UV (EUV) lithography, deep UV (DUV) lithography, or any suitable photolithography technology.

In some embodiments, the radiation generates free acid in the exposed regions of the photoresist layer. The free acid may be generated from the PAG that is present in the photoresist layer under the influence of the radiation. The free acid may react with the material of the photoresist layer and alter the solubility of the exposed regions of the photoresist layer. Subsequently, the exposed regions of the photoresist layer are removed by performing a developing process using a suitable developer (e.g., positive-tone developer). The developing process forms the openings 108 in the photoresist layer that expose portions of the target layer 104. The unexposed regions of the photoresist layer form the plurality of mandrels 106.

In FIG. 1B, a polymer layer 110 is deposited over the mandrels 106. The polymer layer 110 may be also referred to as an overcoat layer. The polymer layer 110 may overfill the openings 108 (see FIG. 1A) such that a top surface of the polymer layer 110 is above top surfaces of the mandrels 106. In some embodiments, the polymer layer 110 may comprise a polymer consisting of a combination of monomer units including structures of moderate polarity such as hydroxy styrene, methyl methacrylate, and methyl acrylic acid, or the like. In some embodiments, the polymer layer 110 may comprise free acid or an agent-generating ingredient such as TAG or PAG as well may also include quencher and/or photo-decomposable base in low concentrations.

In some embodiments, the polymer layer 110 may be deposited using techniques such as spin coating, CVD, ALD, a combination thereof, or the like. The choice of deposition technique may depend on factors such as the desired thickness of the polymer layer 110, its composition, and compatibility with the mandrels 106. For example, the polymer layer 110 may be deposited using a solvent that does not dissolve the material of the mandrels 106. In some embodiments, the solvent may comprise methyl isobutyl carbinol (MIBC), isoamyl ether (IAE), Isobutyl Isobutyrate (IBIB), a combination thereof, or the like of similar polarity.

In FIG. 1C, a thermal treatment may be performed on the structure of FIG. 1B. The thermal treatment may be a single thermal treatment or may comprise multiple thermal treatments performed at different process parameters (e.g., process temperature and time). In some embodiments, the thermal treatment may comprise a post-deposition bake process performed to remove any solvents and stabilize the polymer layer 110. The post-deposition bake process may be performed at a process temperature in a range from 75 °C to 100 °C for a process time in a range from 30 to 180 seconds.

In some embodiments when the polymer layer 110 comprises a TAG that has an activation temperature that is less than the process temperature of the post-deposition bake process, free acid 112 is generated in the polymer layer 110. In other embodiments when the polymer layer 110 comprises a TAG that has an activation temperature that is greater than the process temperature of the post-deposition bake process, no free acid is generated in the polymer layer 110.

In some embodiments, the post-deposition bake process may further cause the free acid 112 to diffuse (as shown by arrows in FIG. 1C) from the polymer layer 110 into the mandrels 106. The diffused free acid 112 reacts with the material of the mandrels 106 and creates deprotected regions 114 within the mandrels 106. Remaining regions of the mandrels 106 form protected regions 116 of the mandrels 106. The deprotected regions 114 of the mandrels 106 may have different chemical properties (e.g., solubility in various solvents) compared to the protected regions 116 of the mandrels 106.

In some embodiments when the polymer layer 110 comprises a TAG that has an activation temperature that is greater than the process temperature of the post-deposition bake process, an additional thermal treatment may be performed on the polymer layer 110 after the post-deposition bake process to generate the free acid 112. The additional thermal treatment may be performed at a process temperature that is greater than the activation temperature of the TAG. In some embodiments, the additional thermal treatment may be performed at a process temperature in a range from 100 °C to 150 °C for a process time in a range from 15 to 120 seconds.

In some embodiments, the additional thermal treatment may further cause the free acid 112 to diffuse from the polymer layer 110 into the mandrels 106 and form the deprotected regions 114 and the protected regions 116 in the mandrels 106. In some embodiments, the free acid 112 may diffuse into to the mandrels 106 to a depth D₁. The depth D₁ may be in a range from 5 to 40 nanometers. The depth D₁ may be controlled by tuning a concentration of the free acid 112, a diffusion coefficient of the free acid 112 in the mandrels 106, a process temperature of the thermal treatment, and/or a process time of the thermal treatment.

In FIG. 1D, the polymer layer 110 (see FIG. 1C) is selectively removed, leaving the mandrels 106 substantially intact. In some embodiments, the selective removal of the polymer layer 110 may be accomplished using a solvent that preferentially dissolves or etches the polymer layer 110 without substantially affecting the mandrels 106. The choice of the solvent depends on the specific compositions of the mandrels 106 and the polymer layer 110. In some embodiments, the solvent may comprise methyl isobutyl carbinol (MIBC), isoamyl ether (IAE), Isobutyl Isobutyrate (IBIB), a combination thereof, or the like of similar polarity.

In FIG. 1E, a polymer layer 118 is deposited over the mandrels 106. The polymer layer 118 may overfill the openings 108 (see FIG. 1D) such that a top surface of the polymer layer 118 is above top surfaces of the mandrels 106. In some embodiments, the polymer layer 118 may comprise a polymer consisting of a combination of monomer units including structures of moderate polarity such as styrene, hydroxystyrene, methyl methacrylate, and methacrylic acid, a combination thereof, or the like and monomer units containing acid labile groups such as t-butyloxycarbonyl (t-BOC), dioxolane (acetal), butylactone, a combination thereof, or the like. In some embodiments, the polymer layer 118 may be free from free acid and agent-generating ingredients.

In some embodiments, the polymer layer 118 may be deposited using techniques such as spin coating, CVD, ALD, a combination thereof, or the like. The choice of deposition technique may depend on factors such as the desired thickness of the polymer layer 118, its composition, and compatibility with the mandrels 106. For example, the polymer layer 118 may be deposited using a solvent that does not dissolve the deprotected regions 114 and the protected regions 116 of the mandrels 106. In some embodiments, the solvent may comprise methyl isobutyl carbinol (MIBC), isoamyl ether (IAE), Isobutyl Isobutyrate (IBIB), a combination thereof, or the like of similar polarity.

In some embodiments, after depositing the polymer layer 118, a post-deposition bake process may be performed on the polymer layer 118 to remove any solvents and stabilize the polymer layer 118. The post-deposition bake process may be performed at a process temperature in a range from 75 °C to 100 °C for a process time in a range from 30 to 180 seconds.

In FIG. 1F, a portion of the polymer layer 118 (see FIG. 1E) is removed to expose the deprotected regions 114 of the mandrels 106, such that remaining portions of the polymer layer 118 form mandrels 120. Furthermore, the deprotected regions 114 of the mandrels 106 (see FIG. 1E) are also removed to form openings 122, which expose the target layer 104. The protected regions 116 of the mandrels 106 (see FIG. 1E) form mandrels 124 on the target layer 104. In some embodiments, the mandrels 120 have a width W₃, which is substantially same as the width W₂ (see FIG. 1A), the openings 122 have a width W₄, which is substantially same as the depth D₁ (see FIG. 1C), and the mandrels 124 have a width W₅, which is equal to W₁−2*D₁ (see FIGS. 1A and 1C).

In some embodiments, the removal process may be performed using a suitable solvent. The solvent may be selected such that it does not substantially dissolve the protected regions 116 of the mandrels 106, moderately dissolves the polymer layer 118, and substantially dissolves the deprotected regions 114 of the mandrels 106 (see FIG. 1E). In other words, the solvent may be selected such that solubility of the protected regions 116 of the mandrels 106 is less than solubility of the polymer layer 118, and the solubility of the polymer layer 118 is less than solubility of the deprotected regions 114 of the mandrels 106 (see FIG. 1E). In some embodiments, the solvent may comprise a polar solvent such as tetramethyl ammonium hydroxide (TMAH) aqueous developer, or the like.

In FIG. 1G, a polymer layer 126 is deposited over the mandrels 120 and 124. The polymer layer 126 may overfill the openings 122 (see FIG. 1F), such that a top surface of the polymer layer 126 is above top surfaces of the mandrels 120 and 124. In some embodiments, the polymer layer 126 may comprise a polymer consisting of a combination of monomer units including structures of low to moderate polarity such as t-butyl styrene, n-butyl methacrylate, methacrylic acid, a combination thereof, or the like. In some embodiments, the polymer layer 126 may comprise free acid or an agent-generating ingredient such as TAG or PAG.

In some embodiments, the polymer layer 126 may be deposited using techniques such as spin coating, CVD, ALD, a combination thereof, or the like. The choice of deposition technique may depend on factors such as the desired thickness of the polymer layer 126, its composition, and compatibility with the mandrels 120 and 124. For example, the polymer layer 126 may be deposited using a solvent that does not dissolve the mandrels 120 and 124. In some embodiments, the solvent may comprise isoamyl ether (IAE), pentanol, a combination thereof, or the like of similar polarity.

In FIG. 1H, a thermal treatment may be performed on the structure of FIG. 1G. The thermal treatment may be a single thermal treatment or may comprise multiple thermal treatments performed at different process parameters (e.g., process temperature and time). In some embodiments, the thermal treatment may comprise a post-deposition bake process performed to remove any solvents and stabilize the polymer layer 126. The post-deposition bake process may be performed at a process temperature in a range from 75 °C to 100 °C for a process time in a range from 30 to 180 seconds.

In some embodiments when the polymer layer 126 comprises a TAG that has an activation temperature that is less than the process temperature of the post-deposition bake process, free acid 128 is generated in the polymer layer 126. In other embodiments when the polymer layer 126 comprises a TAG that has an activation temperature that is greater than the process temperature of the post-deposition bake process, no free acid is generated in the polymer layer 126.

In some embodiments, the post-deposition bake process may further cause the free acid 128 to diffuse (as shown by arrows in FIG. 1H) from the polymer layer 126 into the mandrels 120 and 124. The diffused free acid 128 reacts with the material of the mandrels 120 and creates deprotected regions 134 within the mandrels 120. Remaining regions of the mandrels 120 form protected regions 136 of the mandrels 120. The deprotected regions 134 of the mandrels 120 may have different chemical properties (e.g., solubility in various solvents) compared to the protected regions 136 of the mandrels 120. Furthermore, the diffused free acid 128 reacts with the material of the mandrels 124 and creates deprotected regions 130 within the mandrels 124. Remaining regions of the mandrels 124 form protected regions 132 of the mandrels 124. The deprotected regions 130 of the mandrels 124 may have different chemical properties (e.g., solubility in various solvents) compared to the protected regions 132 of the mandrels 124.

In some embodiments when the polymer layer 126 comprises a TAG that has an activation temperature that is greater than the process temperature of the post-deposition bake process, an additional thermal treatment may be performed on the polymer layer 126 after the post-deposition bake process to generate the free acid 128 in the polymer layer 126. The additional thermal treatment may be performed at a process temperature that is greater than the activation temperature of the TAG. In some embodiments, the additional thermal treatment may be performed at a process temperature in a range from 100 °C to 150 °C for a process time in a range from 15 to 120 seconds.

In some embodiments, the additional thermal treatment may further cause the free acid 128 to diffuse from the polymer layer 126 into the mandrels 120 and 124, and form the deprotected regions 134 and the protected regions 136 in the mandrels 120 and the deprotected regions 130 and the protected regions 132 in the mandrels 124. The free acid 128 may diffuse into to the mandrels 120 to a depth D₂ and into the mandrels 124 to a depth D₃. In some embodiments, the depth D₂ may be same as the depth D₃. In other embodiments, the depth D₂ may be different from the depth D₃. The depth D₂ may be in a range from 5 to 25 nanometers. The depth D₃ may be in a range from 5 to 25 nanometers. The depths D₂ and D₃ may be controlled by tuning a concentration of the free acid 128, diffusion coefficients of the free acid 128 in the mandrels 120 and 124, a process temperature of the thermal treatment, and/or a process time of the thermal treatment.

In FIG. 1I, a portion of the polymer layer 126 (see FIG. 1H) is removed to expose the deprotected regions 134 of the mandrels 120 and the deprotected regions 130 of the mandrels 124, such that remaining portions of the polymer layer 126 form mandrels 138. Furthermore, the deprotected regions 134 of the mandrels 120 (see FIG. 1H) are removed to form openings 146 and the deprotected regions 130 of the mandrels 124 (see FIG. 1H) are removed to form openings 148. The openings 146 and 148 expose the target layer 104. The protected regions 136 of the mandrels 120 (see FIG. 1H) form mandrels 140 on the target layer 104 and the protected regions 132 of the mandrels 124 (see FIG. 1H) form mandrels 142 on the target layer 104. The mandrels 138, 140 and 142 form a patterned mask 144 on the target layer 104.

In some embodiments, the removal process may be performed using a suitable solvent. The solvent may be selected such that it does not substantially dissolve the protected regions 136 of the mandrels 120, does not substantially dissolve the protected regions 132 of the mandrels 124, moderately dissolves the polymer layer 126, substantially dissolves the deprotected regions 134 of the mandrels 120, and substantially dissolves the deprotected regions 130 of the mandrels 120 (see FIG. 1H). In other words, the solvent may be selected such that solubilities of the protected regions 136 of the mandrels 120 and the protected regions 132 of the mandrels 124 are less than solubility of the polymer layer 126, and the solubility of the polymer layer 126 is less than solubilities of the deprotected regions 134 of the mandrels 120 and the deprotected regions 130 of the mandrels 124 (see FIG. 1H). In some embodiments, the solvent may comprise a polar solvent such as standard tetramethyl ammonium hydroxide (TMAH) aqueous developer, or the like.

In some embodiments, the mandrels 138 have a width W₆, which is substantially same as the width W₄ (see FIG. 1F), the mandrels 140 have a width W₇, which is equal to W₃−2*D₂ (see FIGS. 1F and 1H), the mandrels 142 have a width W₈, which is equal to W₅−2*D₃ (see FIGS. 1F and 1H), the openings 146 have a width W₉, which is substantially same as the depth D₂ (see FIG. 1H), and the openings 148 have a width W₁₀, which is substantially same as the depth D₃ (see FIG. 1H). In some embodiments, dimensions (e.g., widths W₆ through W₁₀) of the patterned mask 144 may be smaller than dimensions (e.g., widths W₁ and W₂) of the mandrels 106 and the openings 108 (see FIG. 1A). This reduction in feature size is a result of the controlled acid diffusion process and can be used to achieve patterns with dimensions smaller than those directly achievable through the initial lithography process. In some embodiments, dimensions (e.g., widths W₆ through W₁₀) of the patterned mask 144 may be tuned by tuning the widths W₁ and W₂, and the depths D_{1,} D₂, and D₃ (see FIGS. 1A, 1C, and 1H)_{.} In one embodiment, dimensions (e.g., widths W₆ through W₁₀) of the patterned mask 144 may be tuned such that the widths W₆ through W₁₀ are equal to each other.

In FIG. 1J, a pattern defined by the patterned mask 144 is transferred to the target layer 104. In some embodiments, the pattern transfer may be accomplished through an etching process. The etching process selectively removes portions of the target layer 104 that are not protected by the patterned mask 144, resulting in the formation of the patterned target layer. In some embodiments, the etching process may be a dry etching technique such as reactive ion etching (RIE), plasma etching, or ion beam etching. In other embodiments, wet etching techniques may be employed. In some embodiment, the pattern transfer process may be followed by the removal of any remaining patterned mask 144. The removal can be accomplished using suitable solvents, plasma ashing techniques, or the like, leaving the patterned target layer 104 on the substrate 102.

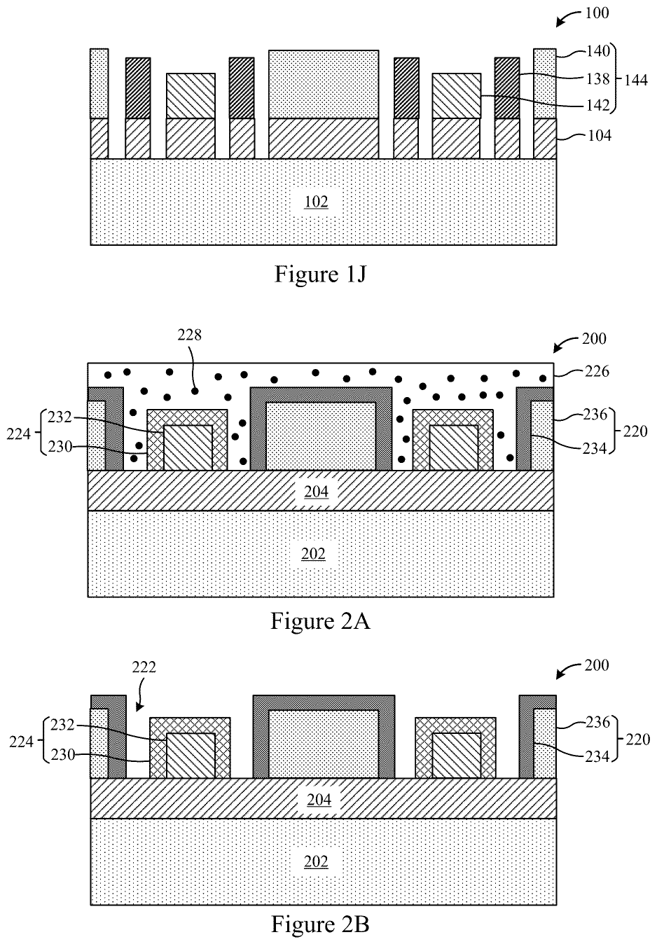

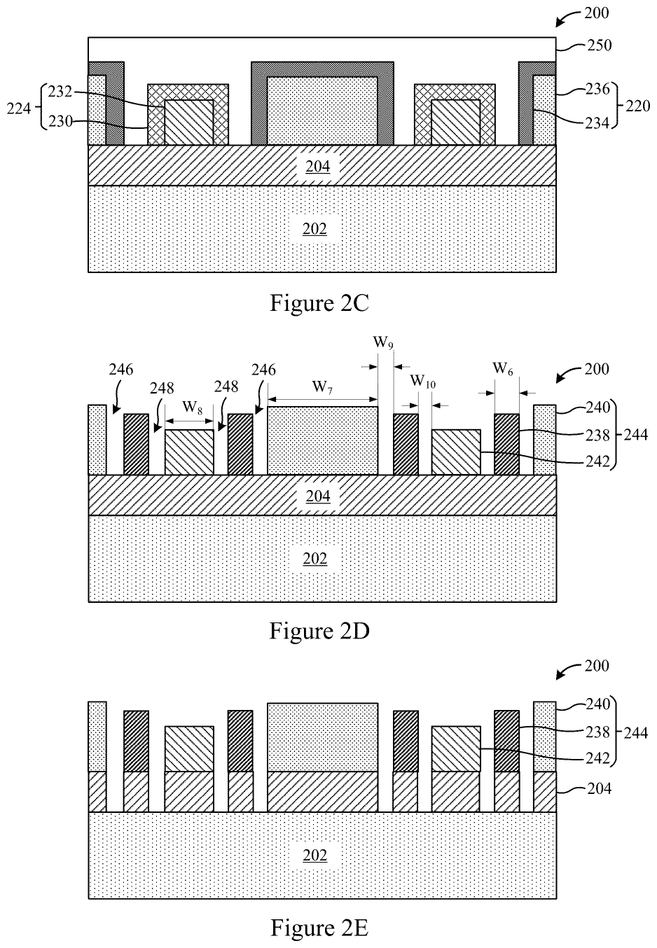

FIGS. 2A-2E illustrate cross-sectional views of intermediate stages in the manufacturing of a patterned mask over a substrate in accordance with various embodiments. Unless otherwise indicated, features 2xx of FIGS. 2A-2E may be similar to features 1xx of FIGS. 1A-1J, may be formed using materials and methods that are similar to those described above with reference to FIGS. 1A-1J, and descriptions of the similar features are not repeated herein.

In FIG. 2A, a semiconductor structure 200 is illustrated. The semiconductor structure 200 may be similar to the semiconductor structure 100 illustrated in FIG. 1H, with features 2xx being similar to features 1xx, and descriptions of the similar features are not repeated herein. In some embodiments, the semiconductor structure 200 of FIG. 2A may be formed using materials and methods that are similar to those described above with reference to FIGS. 1A-1H, and description is not repeated herein.

In some embodiments, the semiconductor structure 200 comprises a substrate 202 and a target layer 204 over the substrate 202. The semiconductor structure 200 further comprises mandrels 220 and 224 over the target layer 204 and a polymer layer 226 over the mandrels 220 and 224. The mandrels 220 comprise deprotected regions 234 and protected regions 236. The mandrels 224 comprise deprotected regions 230 and protected regions 232. In some embodiments, a top surface of the polymer layer 226 is above top surfaces of the mandrels 220 and 224.

In FIG. 2B, the polymer layer 226 (see FIG. 2A) is selectively removed, leaving the mandrels 220 and 224 substantially intact. In some embodiments, the selective removal of the polymer layer 226 may be accomplished using a solvent that preferentially dissolves or etches the polymer layer 226 without substantially affecting the mandrels 220 and 224. The choice of the solvent depends on the specific compositions of the mandrels 220 and 224, and the polymer layer 226. In some embodiments, the solvent may comprise isoamyl ether, n-pentanol or similar non-polar solvents as the majority composition or a combination thereof, or the like.

In FIG. 2C, a polymer layer 250 is deposited over the mandrels 220 and 224. The polymer layer 250 may overfill the openings 222 (see FIG. 2B) such that a top surface of the polymer layer 250 is above top surfaces of the mandrels 220 and 224. In some embodiments, the polymer layer 250 may comprise a polymer material such as t-butyl styrene or n-butyl methacrylate as majority components and a minority polar monomer such as methacrylic acid or butyl lactone or a combination thereof, or the like. In some embodiments, the polymer layer 250 may be free from free acid and agent-generating ingredients.

In some embodiments, the polymer layer 250 may be deposited using techniques such as spin coating, CVD, ALD, a combination thereof, or the like. The choice of deposition technique may depend on factors such as the desired thickness of the polymer layer 250, its composition, and compatibility with the mandrels 220 and 224. For example, the polymer layer 250 may be deposited using a solvent that does not dissolve the deprotected regions 234 and the protected regions 236 of the mandrels 220 and the deprotected regions 230 and the protected regions 232 of the mandrels 224. In some embodiments, the solvent may comprise isoamyl ether, n-pentanol or similar non-polar solvents as the majority composition or a combination thereof, or the like.

In some embodiments, after depositing the polymer layer 250, a post-deposition bake process may be performed on the polymer layer 250 to remove any solvents and stabilize the polymer layer 250. The post-deposition bake process may be performed at a process temperature in a range from 75 °C to 100 °C for a process time in a range from 30 to 180 seconds.

In FIG. 2D, a portion of the polymer layer 250 is removed to expose the deprotected regions 234 the mandrels 220 and the deprotected regions 230 of the mandrels 224 (see FIG. 2C), such that remaining portions of the polymer layer 250 form mandrels 238. Furthermore, the deprotected regions 234 of the mandrels 220 (see FIG. 2C) are removed to form openings 246 and the deprotected regions 230 of the mandrels 224 (see FIG. 2C) are removed to form openings 248. The openings 246 and 248 expose the target layer 204. The protected regions 236 of the mandrels 220 (see FIG. 2C) form mandrels 240 on the target layer 204 and the protected regions 232 of the mandrels 224 (see FIG. 2C) form mandrels 242 on the target layer 204. The mandrels 238, 240 and 242 form a patterned mask 244 on the target layer 204.

In some embodiments, the removal process may be performed using a suitable solvent. The solvent may be selected such that it does not substantially dissolve the protected regions 236 of the mandrels 220, does not substantially dissolve the protected regions 232 of the mandrels 224, moderately dissolves the polymer layer 250, substantially dissolves the deprotected regions 234 of the mandrels 220, and substantially dissolves the deprotected regions 230 of the mandrels 220 (see FIG. 2C). In other words, the solvent may be selected such that solubilities of the protected regions 236 of the mandrels 220 and the protected regions 232 of the mandrels 224 are less than solubility of the polymer layer 250, and the solubility of the polymer layer 250 is less than solubilities of the deprotected regions 234 of the mandrels 220 and the deprotected regions 230 of the mandrels 224 (see FIG. 2C). In some embodiments, the solvent may comprise a polar solvent such as tetramethyl ammonium hydroxide (TMAH) aqueous developer, or the like.

In FIG. 2E, a pattern defined by the patterned mask 244 is transferred to the target layer 204 (see FIG. 2D). In some embodiments, the pattern transfer may be accomplished through an etching process. The etching process selectively removes portions of the target layer 204 that are not protected by the patterned mask 244, resulting in the formation of the patterned target layer. In some embodiments, the etching process may be a dry etching technique such as reactive ion etching (RIE), plasma etching, or ion beam etching. In other embodiments, wet etching techniques may be employed. In some embodiment, the pattern transfer process may be followed by the removal of any remaining patterned mask 244. The removal can be accomplished using suitable solvents, plasma ashing techniques, or the like, leaving the patterned target layer 204 on the substrate 202.

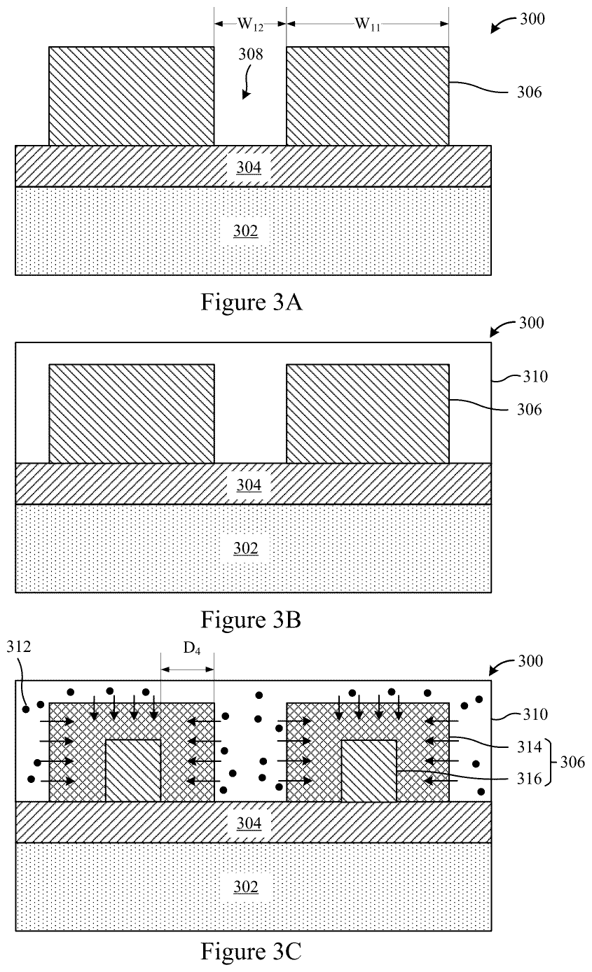

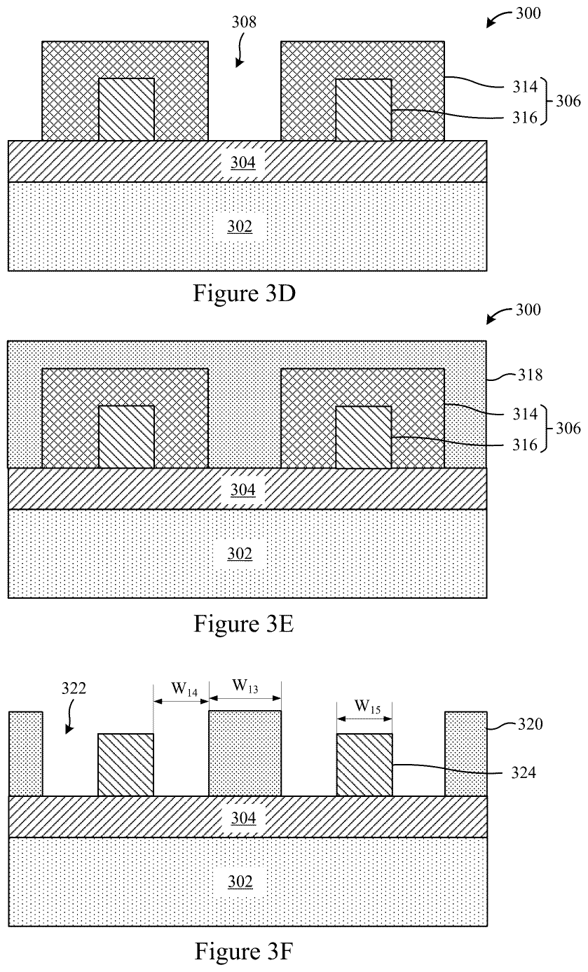

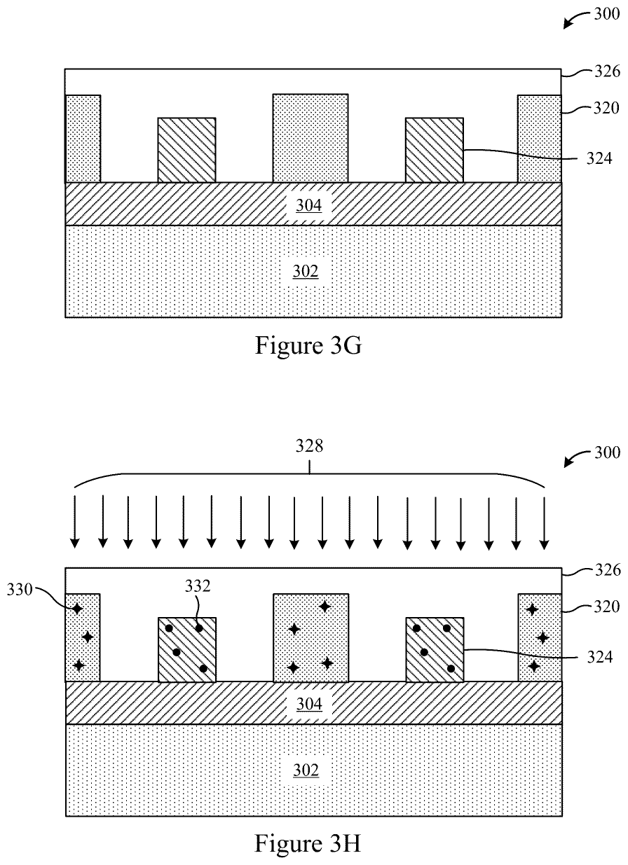

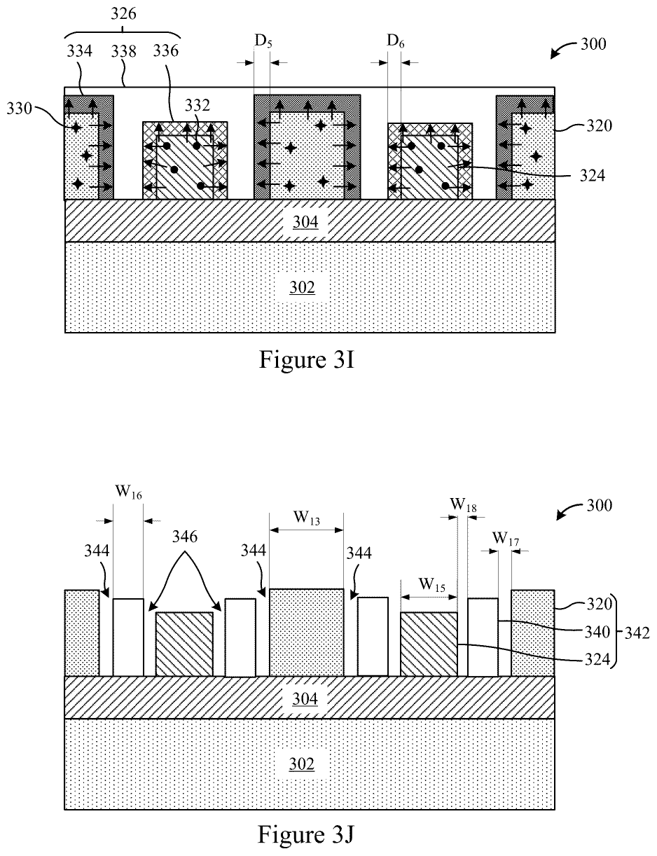

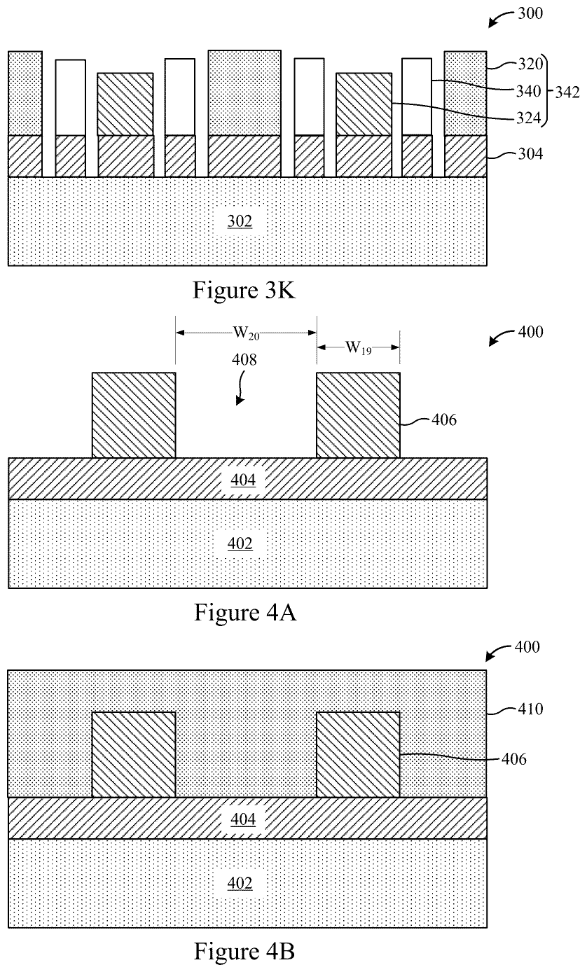

FIGS. 3A-3K illustrate cross-sectional views of intermediate stages in the manufacturing of a patterned mask over a substrate in accordance with various embodiments. In FIG. 3A, a semiconductor structure 300 is illustrated. The semiconductor structure 200 may include a substrate 302. The substrate 302 may be similar to the substrate 102 described above with reference to FIG. 1A, and the description is not repeated herein. In some embodiments, a target layer 304 is formed over the substrate 302. The target layer 304 represents a layer that will be subsequently patterned. The target layer 304 may be formed using similar materials and methods as the target layer 104 described above with reference to FIG. 1A, and the description is not repeated herein.

In some embodiments, mandrels 306 are formed over the target layer 304. The mandrels 306 may be separated by openings 308. The openings 308 define areas where the underlying target layer 304 is exposed. The mandrels 306 may have a width W₁₁ and the openings 308 may have a width W₁₂. The width W₁₁ may be same as or different from the width W₁₂. In some embodiments, the mandrels 306 may be formed using similar materials and methods as the mandrels 106 described above with reference to FIG. 1A, and the description is not repeated herein.

In FIG. 3B, a polymer layer 310 is deposited over the mandrels 306. The polymer layer 310 may be also referred to as an overcoat layer. The polymer layer 310 may overfill the openings 308 (see FIG. 3A) such that a top surface of the polymer layer 310 is above top surfaces of the mandrels 306. In some embodiments, the polymer layer 310 may be formed using similar material and methods as the polymer layer 110 described above with reference to FIG. 1B, and the description is not repeated herein. In some embodiments, the polymer layer 310 may comprise free acid or an agent-generating ingredient such as TAG or PAG.

In FIG. 3C, a thermal treatment may be performed on the structure of FIG. 3B. The thermal treatment may be a single thermal treatment or may comprise multiple thermal treatments performed at different process parameters (e.g., process temperature and time). In some embodiments, the thermal treatment may comprise a post-deposition bake process performed to remove any solvents and stabilize the polymer layer 310. The post-deposition bake process may be performed at a process temperature in a range from 90 °C to 100 °C for a process time in a range from 30 to 180 seconds.

In some embodiments when the polymer layer 310 comprises a TAG that has an activation temperature that is less than the process temperature of the post-deposition bake process, free acid 312 is generated in the polymer layer 310. In other embodiments when the polymer layer 310 comprises a TAG that has an activation temperature that is greater than the process temperature of the post-deposition bake process, no free acid is generated in the polymer layer 310.

In some embodiments, the post-deposition bake process may further cause the free acid 312 to diffuse (as shown by arrows in FIG. 3C) from the polymer layer 310 into the mandrels 306. The diffused free acid 312 reacts with the material of the mandrels 306 and creates deprotected regions 314 within the mandrels 306. Remaining regions of the mandrels 306 form protected regions 316 of the mandrels 306. The deprotected regions 314 of the mandrels 306 may have different chemical properties (e.g., solubility in various solvents) compared to the protected regions 316 of the mandrels 306.

In some embodiments when the polymer layer 310 comprises a TAG that has an activation temperature that is greater than the process temperature of the post-deposition bake process, an additional thermal treatment may be performed on the polymer layer 310 after the post-deposition bake process to generate the free acid 312. The additional thermal treatment may be performed at a process temperature that is greater than the activation temperature of the TAG. In some embodiments, the additional thermal treatment may be performed at a process temperature in a range from 100 °C to 150 °C for a process time in a range from 15 to 120 seconds.

In some embodiments, the additional thermal treatment may further cause the free acid 312 to diffuse from the polymer layer 310 into the mandrels 306 and form the deprotected regions 314 and the protected regions 316 in the mandrels 306. In some embodiments, the free acid 312 may diffuse into to the mandrels 306 to a depth D₄. The depth D₄ may be in a range from 20 to 70 nanometers. The depth D₄ may be controlled by tuning a concentration of the free acid 312, a diffusion coefficient of the free acid 312 in the mandrels 306, a process temperature of the thermal treatment, and/or a process time of the thermal treatment.

In FIG. 3D, the polymer layer 310 (see FIG. 3C) is selectively removed, leaving the mandrels 306 substantially intact. In some embodiments, the selective removal of the polymer layer 310 may be accomplished using a solvent that preferentially dissolves or etches the polymer layer 310 without substantially affecting the mandrels 306. The choice of the solvent depends on the specific compositions of the mandrels 306 and the polymer layer 310. In some embodiments, the solvent may comprise methyl isobutyl carbinol (MIBC), isoamyl ether (IAE), Isobutyl Isobutyrate (IBIB), a combination thereof, or the like.

In FIG. 3E, a polymer layer 318 is deposited over the mandrels 306. The polymer layer 318 may overfill the openings 308 (see FIG. 3D) such that a top surface of the polymer layer 318 is above top surfaces of the mandrels 306. In some embodiments, the polymer layer 318 may comprise a polymer material such as styrene, hydroxystyrene, methyl methacrylate, t-butoxy carbonyl or a combination thereof, or the like. In some embodiments, the polymer layer 318 may comprise an agent-generating ingredient such as PAG.

In some embodiments, the polymer layer 318 may be deposited using techniques such as spin coating, CVD, ALD, a combination thereof, or the like. The choice of deposition technique may depend on factors such as the desired thickness of the polymer layer 318, its composition, and compatibility with the mandrels 306. For example, the polymer layer 318 may be deposited using a solvent that does not dissolve the deprotected regions 314 and the protected regions 316 of the mandrels 306. In some embodiments, the solvent may comprise methyl isobutyl carbinol (MIBC), isoamyl ether (IAE), Isobutyl Isobutyrate (IBIB), a combination thereof, or the like.

In some embodiments, after depositing the polymer layer 318, a post-deposition bake process may be performed on the polymer layer 318 to remove any solvents and stabilize the polymer layer 318. The post-deposition bake process may be performed at a process temperature in a range from 75 °C to 100 °C for a process time in a range from 30 to 180 seconds.

In FIG. 3F, a portion of the polymer layer 318 (see FIG. 3E) is removed to expose the deprotected regions 314 of the mandrels 306, such that remaining portions of the polymer layer 318 form mandrels 320. Furthermore, the deprotected regions 314 of the mandrels 306 (see FIG. 3E) are removed to form openings 322, which expose the target layer 304. The protected regions 316 of the mandrels 306 (see FIG. 3E) form mandrels 324 on the target layer 304. In some embodiments, the mandrels 320 have a width W₁₃, which is substantially same as the width W₁₂ (see FIG. 3A), the openings 322 have a width W₁₄, which is substantially same as the depth D₄ (see FIG. 3C), and the mandrels 324 have a width W₁₅, which is equal to W₁₁−2*D₄ (see FIGS. 3A and 3C).

In some embodiments, the removal process may be performed using a suitable solvent. The solvent may be selected such that it does not substantially dissolve the protected regions 316 of the mandrels 306, moderately dissolves the polymer layer 318, and substantially dissolves the deprotected regions 314 of the mandrels 306 (see FIG. 3E). In other words, the solvent may be selected such that solubility of the protected regions 316 of the mandrels 306 is less than solubility of the polymer layer 318, and the solubility of the polymer layer 318 is less than solubility of the deprotected regions 314 of the mandrels 306 (see FIG. 3E). In some embodiments, the solvent may comprise methyl isobutyl carbinol (MIBC), isoamyl ether (IAE), Isobutyl Isobutyrate (IBIB), a combination thereof, or the like.

In FIG. 3G, a polymer layer 326 is deposited over the mandrels 320 and 324. The polymer layer 326 may overfill the openings 322 (see FIG. 3F), such that a top surface of the polymer layer 326 is above top surfaces of the mandrels 320 and 324. In some embodiments, the polymer layer 326 may comprise a polymer material with a majority backbone such as t-butyl styrene or n-butyl methacrylate with additional minority components composed of low activation energy acid labile pendant groups such as 1-Ethylcyclopentyl methacrylate or an acetal moiety, a combination thereof, or the like. In some embodiments, the polymer layer 126 may be free from free acid or agent-generating ingredients.

In some embodiments, the polymer layer 326 may be deposited using techniques such as spin coating, CVD, ALD, a combination thereof, or the like. The choice of deposition technique may depend on factors such as the desired thickness of the polymer layer 326, its composition, and compatibility with the mandrels 320 and 324. For example, the polymer layer 326 may be deposited using a solvent that does not dissolve the mandrels 320 and 324. In some embodiments, the solvent may comprise isoamyl ether, n-pentanol, or similar non-polar solvents as the majority composition, or a combination thereof, or the like.

In FIG. 3H, the mandrels 320 and 324 are exposed to a radiation 328 (e.g., actinic radiation) though the polymer layer 326. In some embodiments, when the mandrels 320 and 324 comprise PAG, the radiation 328 generates free acid 330 in the mandrels 320 and free acid 332 in the mandrels 324. The free acids 330 and 332 may have same or different concentrations. The free acids 330 and 332 may have same or different compositions.

In FIG. 3I, a thermal treatment is performed in the structure of FIG. 3H. In some embodiments, the thermal treatment may be performed at a process temperature in a range from 75 °C to 120 °C for a process time in a range from 30 to 180 seconds. In some embodiments, the thermal treatment may cause the free acids 330 and 332 to diffuse (as shown by arrows in FIG. 3I) from the mandrels 320 and 324, respectively, into the polymer layer 326. The diffused free acid 330 reacts with the material of the polymer layer 326 and creates deprotected regions 334 within the polymer layer 326. The diffused free acid 332 reacts with the material of the polymer layer 326 and creates deprotected regions 336 within the polymer layer 326. A remaining region of the polymer layer 326 forms a protected region 338 of the polymer layer 326. The deprotected regions 334 and 336 of the polymer layer 326 may have different chemical properties (e.g., solubility in various solvents) compared to the protected region 338 of the polymer layer 326.

The free acid 330 may diffuse into to the polymer layer 326 to a depth D₅. The free acid 332 may diffuse into to the polymer layer 326 to a depth D₆. In some embodiments, the depth D₅ may be same as the depth D₆. In other embodiments, the depth D₅ may be different from the depth D₆. The depth D₅ may be in a range from 5 to 25 nanometers. The depth D₆ may be in a range from 5 to 25 nanometers. The depth D₅ may be controlled by tuning a concentration of the free acid 330, a diffusion coefficient of the free acid 330 in the polymer layer 326, a process temperature of the thermal treatment, and/or a process time of the thermal treatment. The depth D₆ may be controlled by tuning a concentration of the free acid 332, a diffusion coefficient of the free acid 332 in the polymer layer 326, a process temperature of the thermal treatment, and/or a process time of the thermal treatment.

In FIG. 3J, a portion of the protected region 338 of the polymer layer 326 is removed to expose the deprotected regions 334 and 336 of the polymer layer 326 (see FIG. 3I), such that remaining portions of the protected region 338 form mandrels 340. Furthermore, the deprotected regions 334 of the polymer layer 326 (see FIG. 3I) are removed to form openings 344 and the deprotected regions 336 of the polymer layer 326 are removed to form openings 346. The openings 344 and 346 expose the target layer 304. The mandrels 320, 324 and 340 form a patterned mask 342 on the target layer 304.

In some embodiments, the removal process may be performed using a suitable solvent. The solvent may be selected such that it does not substantially dissolve the mandrels 320 and 324, moderately dissolves the protected region 338 of the polymer layer 326, substantially dissolves the deprotected regions 334 and 336 of the polymer layer 326 (see FIG. 3I). In other words, the solvent may be selected such that solubilities of the mandrels 320 and 324 are less than solubility of the protected region 338 of the polymer layer 326, and the solubility of the protected region 338 of the polymer layer 326 is less than solubilities of deprotected regions 334 and 336 of the polymer layer 326 (see FIG. 3I). In some embodiments, the solvent may comprise a polar solvent such as standard tetramethyl ammonium hydroxide (TMAH) aqueous developer, or the like.

In some embodiments, the mandrels 340 have a width W₁₆, which is equal to W₁₄−D₅−D₆ (see FIGS. 3F and 3I), the openings 344 have a width W₁₇, which is substantially same as the depth D₅ (see FIG. 3I), and the openings 346 have a width W₁₈, which is substantially same as the depth D₆ (see FIG. 3I). In some embodiments, dimensions (e.g., widths W₁₃ and W₁₅ through W₁₈) of the patterned mask 342 may be smaller than dimensions (e.g., widths W₁₁ and W₁₂) of the mandrels 306 and the openings 308 (see FIG. 3A). This reduction in feature size is a result of the controlled acid diffusion process and can be used to achieve patterns with dimensions smaller than those directly achievable through the initial lithography process. In some embodiments, dimensions (e.g., widths W₁₃ and W₁₅ through W₁₈) of the patterned mask 342 may be tuned by tuning the widths W₁ and W₂, and the depths D₄, D₅, and D₆ (see FIGS. 3A, 3C and 3I)_{.} In one embodiment, dimensions (e.g., widths W₁₃ and W₁₅ through W₁₈) of the patterned mask 342 may be tuned such that the widths W₁₃ and W₁₅ through W₁₈ are equal to each other.

In FIG. 3K, a pattern defined by the patterned mask 342 is transferred to the target layer 304. In some embodiments, the pattern transfer may be accomplished through an etching process. The etching process selectively removes portions of the target layer 304 that are not protected by the patterned mask 342, resulting in the formation of the patterned target layer. In some embodiments, the etching process may be a dry etching technique such as reactive ion etching (RIE), plasma etching, or ion beam etching. In other embodiments, wet etching techniques may be employed. In some embodiment, the pattern transfer process may be followed by the removal of any remaining patterned mask 342. The removal can be accomplished using suitable solvents, plasma ashing techniques, or the like, leaving the patterned target layer 304 on the substrate 302.

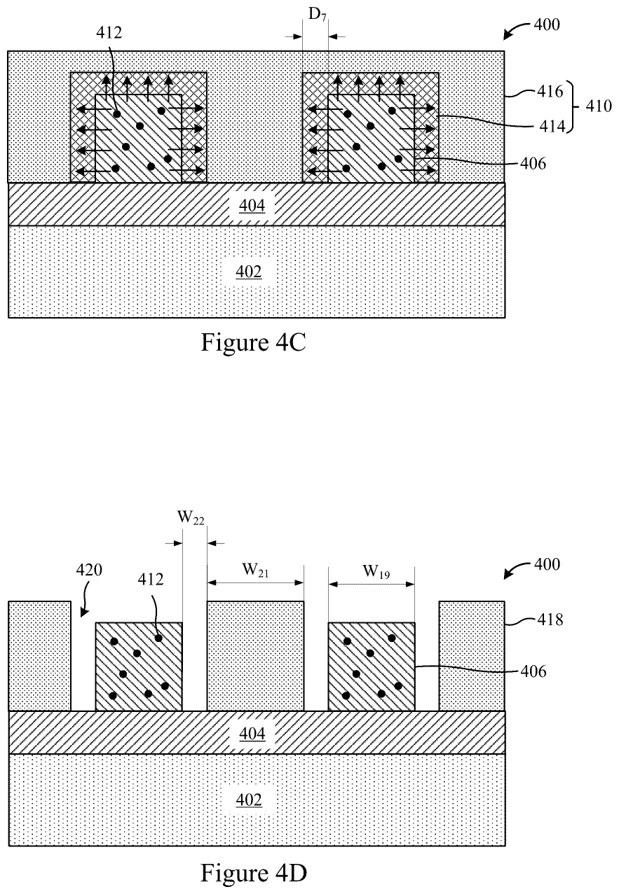

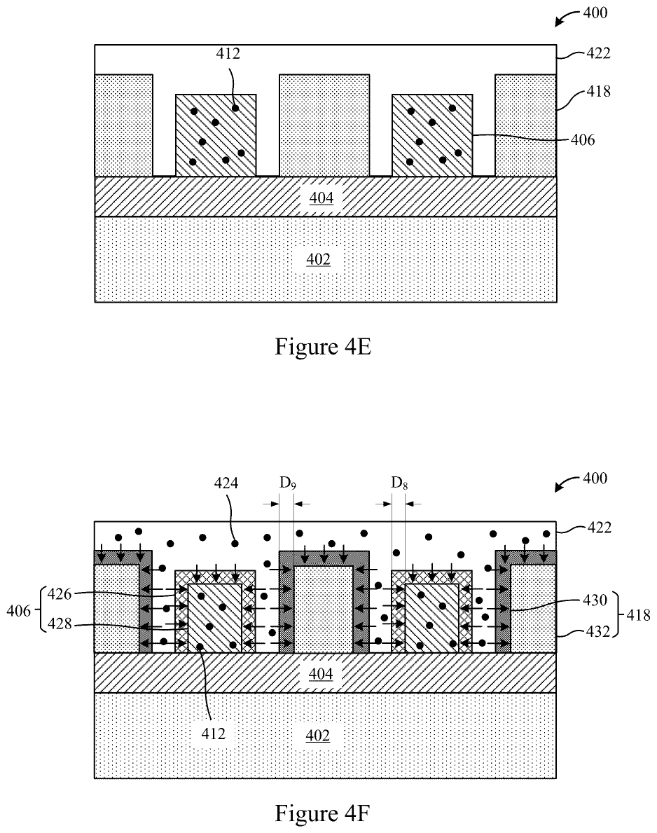

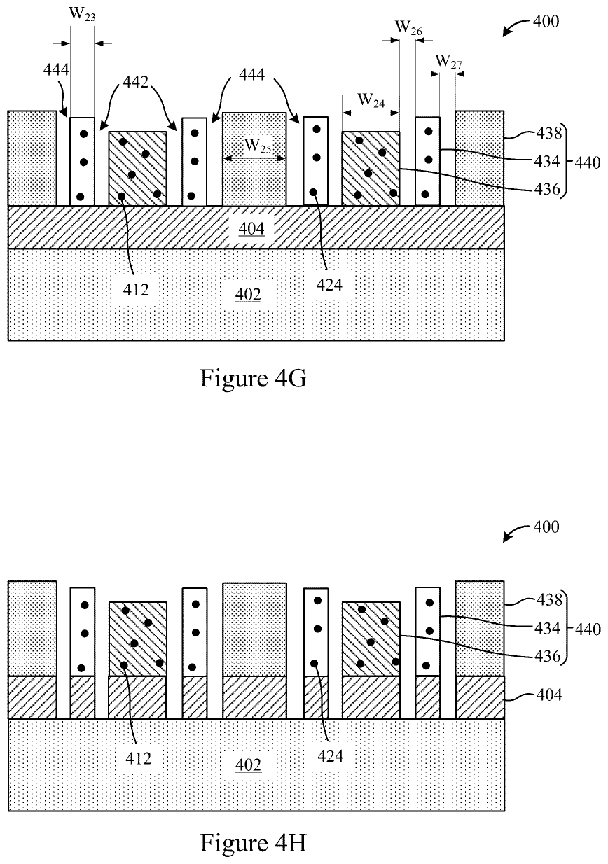

FIGS. 4A-4H illustrate cross-sectional views of intermediate stages in the manufacturing of a patterned mask over a substrate in accordance with various embodiments. In FIG. 4A, a semiconductor structure 400 is illustrated. The semiconductor structure 400 may include a substrate 402. The substrate 402 may be similar to the substrate 102 described above with reference to FIG. 1A, and the description is not repeated herein. In some embodiments, a target layer 404 is formed over the substrate 402. The target layer 404 represents a layer that will be subsequently patterned. The target layer 404 may be formed using similar materials and methods as the target layer 104 described above with reference to FIG. 1A, and the description is not repeated herein.

In some embodiments, mandrels 406 are formed over the target layer 404. The mandrels 406 may be separated by openings 408. The openings 408 define areas where the underlying target layer 404 is exposed. The mandrels 406 may have a width W₁₉ and the openings 408 may have a width W₂₀. The width W₁₉ may be same as or different from the width W₂₀. In some embodiments, the mandrels 406 may be formed using similar materials and methods as the mandrels 106 described above with reference to FIG. 1A, and the description is not repeated herein. In some embodiments, the mandrels 406 may comprise both TAG and PAG.

In FIG. 4B, a polymer layer 410 is deposited over the mandrels 406. The polymer layer 410 may be also referred to as an overcoat layer. The polymer layer 410 may overfill the openings 408 (see FIG. 4A) such that a top surface of the polymer layer 410 is above top surfaces of the mandrels 406. In some embodiments, the polymer layer 410 may comprise a polymer with majority backbone such as t-butyl styrene or n-butyl methacrylate with additional minority components composed of low activation energy acid labile pendant groups such as 1-Ethylcyclopentyl methacrylate or an acetal moiety, a combination thereof, or the like. In some embodiments, the polymer layer 410 may be free from free acid and agent-generating ingredients.

In some embodiments, the polymer layer 410 may be deposited using techniques such as spin coating, CVD, ALD, a combination thereof, or the like. The choice of deposition technique may depend on factors such as the desired thickness of the polymer layer 410, its composition, and compatibility with the mandrels 406. For example, the polymer layer 410 may be deposited using a solvent that does not dissolve the mandrels 406. In some embodiments, the solvent may comprise methyl isobutyl carbinol (MIBC), isoamyl ether (IAE), Isobutyl Isobutyrate (IBIB), a combination thereof, or the like.

In FIG. 4C, a thermal treatment may be performed on the structure of FIG. 4B. The thermal treatment may be a single thermal treatment or may comprise multiple thermal treatments performed at different process parameters (e.g., process temperature and time). In some embodiments, the thermal treatment may comprise a post-deposition bake process performed to remove any solvents and stabilize the polymer layer 410. The post-deposition bake process may be performed at a process temperature in a range from 75 °C to 100 °C for a process time in a range from 30 to 180 seconds.

In some embodiments when the mandrels 406 comprise a TAG that has an activation temperature that is less than the process temperature of the post-deposition bake process, free acid 412 is generated in the mandrels 406. In other embodiments when the mandrels 406 comprises a TAG that has an activation temperature that is greater than the process temperature of the post-deposition bake process, no free acid is generated in the mandrels 406. In some embodiments, a concentration of the free acid 412 is such that the free acid 412 does not generate deprotected regions in the mandrels 406. In other words, a concentration of the free acid 412 is such that the free acid 412 does not alter solubility of the mandrels 406.

In some embodiments, the post-deposition bake process may further cause the free acid 412 to diffuse (as shown by arrows in FIG. 4C) from the mandrels 406 into the polymer layer 410. The diffused free acid 412 reacts with the material of the polymer layer 410 and creates deprotected regions 414 within the polymer layer 410. A remaining region of the polymer layer 410 forms a protected region 416 of the polymer layer 410. The deprotected regions 414 of the polymer layer 410 may have different chemical properties (e.g., solubility in various solvents) compared to the protected region 416 of the polymer layer 410.

In some embodiments when the mandrels 406 comprise a TAG that has an activation temperature that is greater than the process temperature of the post-deposition bake process, an additional thermal treatment may be performed on the structure of FIG. 4B after the post-deposition bake process to generate the free acid 412 in the mandrels 406. In some embodiments, a concentration of the free acid 412 is such that the free acid 412 does not generate deprotected regions in the mandrels 406. The additional thermal treatment may be performed at a process temperature that is greater than the activation temperature of the TAG. In some embodiments, the additional thermal treatment may be performed at a process temperature in a range from 100 °C to 150 °C for a process time in a range from 15 to 120 seconds.

In some embodiments, the additional thermal treatment may further cause the free acid 412 to diffuse from the mandrels 406 into the polymer layer 410 and form the deprotected regions 414 and the protected region 416 in the polymer layer 410. In some embodiments, the free acid 412 may diffuse into to the polymer layer 410 to a depth D₇. The depth D₇ may be in a range from 15 to 40 nanometers. The depth D₇ may be controlled by tuning a concentration of the free acid 412, a diffusion coefficient of the free acid 412 in the polymer layer 410, a process temperature of the thermal treatment, and/or a process time of the thermal treatment.

In FIG. 4D, a portion of the protected region 416 of the polymer layer 410 (see FIG. 4C) is removed to expose the deprotected regions 414 of the polymer layer 410, such that remaining portions of the protected region 416 of the polymer layer 410 form mandrels 418 on the target layer 404. Furthermore, the deprotected regions 414 of the polymer layer 410 (see FIG. 4C) are removed to form openings 420, which expose the target layer 404. In some embodiments, the mandrels 418 have a width W₂₁, which is equal to W₂₀−2*D₇ (see FIGS. 4A and 4C) and the openings 420 have a width W₂₂, which is substantially same as the depth D₇ (see FIG. 4C).

In some embodiments, the removal process may be performed using a suitable solvent. The solvent may be selected such that it does not substantially dissolve the mandrels 406, moderately dissolves the protected region 416 of the polymer layer 410, and substantially dissolves the deprotected regions 414 of the polymer layer 410 (see FIG. 4C). In other words, the solvent may be selected such that solubility of the mandrels 406 is less than solubility of the protected region 416 of the polymer layer 410, and the solubility of the protected region 416 of the polymer layer 410 is less than solubility of the deprotected regions 414 of the polymer layer 410 (see FIG. 4C). In some embodiments, the solvent may comprise a polar solvent such as standard tetramethyl ammonium hydroxide (TMAH) aqueous developer, or the like.

In FIG. 4E, a polymer layer 422 is deposited over the mandrels 406 and 418. The polymer layer 422 may overfill the openings 420 (see FIG. 4D), such that a top surface of the polymer layer 422 is above top surfaces of the mandrels 406 and 418. In some embodiments, the polymer layer 422 may comprise a polymer material with majority backbone such as t-butyl styrene or n-butyl methacrylate with additional minority components such as methyl methacrylate or methacrylic acid or a combination thereof, or the like. In some embodiments, the polymer layer 422 may comprise free acid or an agent-generating ingredient such as TAG or PAG.

In some embodiments, the polymer layer 422 may be deposited using techniques such as spin coating, CVD, ALD, a combination thereof, or the like. The choice of deposition technique may depend on factors such as the desired thickness of the polymer layer 422, its composition, and compatibility with the mandrels 406 and 418. For example, the polymer layer 422 may be deposited using a solvent that does not dissolve the mandrels 406 and 418. In some embodiments, the solvent may comprise isoamyl ether, n-pentanol, or similar non-polar solvents as the majority composition, a combination thereof, or the like.

In FIG. 4F, a thermal treatment may be performed on the structure of FIG. 4E. The thermal treatment may be a single thermal treatment or may comprise multiple thermal treatments performed at different process parameters (e.g., process temperature and time). In some embodiments, the thermal treatment may comprise a post-deposition bake process performed to remove any solvents and stabilize the polymer layer 422. The post-deposition bake process may be performed at a process temperature in a range from 75 °C to 100 °C for a process time in a range from 30 to 180 seconds.

In some embodiments when the polymer layer 422 comprises a TAG that has an activation temperature that is less than the process temperature of the post-deposition bake process, free acid 424 is generated in the polymer layer 422. In other embodiments when the polymer layer 422 comprises a TAG that has an activation temperature that is greater than the process temperature of the post-deposition bake process, no free acid is generated in the polymer layer 422.

In some embodiments, the post-deposition bake process may further cause the free acid 424 to diffuse (as shown by arrows in FIG. 4F) from the polymer layer 422 into the mandrels 406 and 418. The diffused free acid 424 reacts with the material of the mandrels 406 and creates deprotected regions 426 within the mandrels 406. Remaining regions of the mandrels 406 form protected regions 428 of the mandrels 406. The deprotected regions 426 of the mandrels 406 may have different chemical properties (e.g., solubility in various solvents) compared to the protected regions 428 of the mandrels 406. The diffused free acid 424 reacts with the material of the mandrels 418 and creates deprotected regions 430 within the mandrels 418. Remaining regions of the mandrels 418 form protected regions 432 of the mandrels 418. The deprotected regions 430 of the mandrels 418 may have different chemical properties (e.g., solubility in various solvents) compared to the protected regions 432 of the mandrels 418.

In some embodiments when the polymer layer 422 comprises a TAG that has an activation temperature that is greater than the process temperature of the post-deposition bake process, an additional thermal treatment may be performed on the structure of FIG. 4E after the post-deposition bake process to generate the free acid 424 in the polymer layer 422. The additional thermal treatment may be performed at a process temperature that is greater than the activation temperature of the TAG. In some embodiments, the additional thermal treatment may be performed at a process temperature in a range from 100 °C to 150 °C for a process time in a range from 15 to 120 seconds.

In some embodiments, the additional thermal treatment may further cause the free acid 424 to diffuse from the polymer layer 422 into the mandrels 406 and 418, and form the deprotected regions 426 and the protected regions 428 in the mandrels 406 and the deprotected regions 430 and the protected regions 432 in the mandrels 418. The free acid 424 may diffuse into to the mandrels 406 to a depth D₈ and into the mandrels 418 to a depth D₉. In some embodiments, the depth D₈ may be same as the depth D₉. In other embodiments, the depth D₈ may be different from the depth D₉. The depth D₈ may be in a range from 5 to 25 nanometers. The depth D₉ may be in a range from 5 to 25 nanometers. The depths D₈ and D₉ may be controlled by tuning a concentration of the free acid 424, diffusion coefficients of the free acid 424 in the mandrels 406 and 418, a process temperature of the thermal treatment, and/or a process time of the thermal treatment.

In FIG. 4G, a portion of the polymer layer 422 (see FIG. 4F) is removed to expose the deprotected regions 426 of the mandrels 406 and the deprotected regions 430 of the mandrels 418, such that remaining portions of the polymer layer 422 form mandrels 434 on the target layer 404. Furthermore, the deprotected regions 426 of the mandrels 406 (see FIG. 4F) are removed to form openings 442 and the deprotected regions 430 of the mandrels 418 (see FIG. 4F) are removed to form openings 444. The openings 442 and 444 expose the target layer 404. The protected regions 428 of the mandrels 406 (see FIG. 4F) form mandrels 436 on the target layer 404 and the protected regions 432 of the mandrels 418 (see FIG. 4F) form mandrels 438 on the target layer 404. The mandrels 434, 436 and 438 form a patterned mask 440 on the target layer 404.

In some embodiments, the removal process may be performed using a suitable solvent. The solvent may be selected such that it does not substantially dissolve the protected regions 428 of the mandrels 406, does not substantially dissolve the protected regions 432 of the mandrels 418, moderately dissolves the polymer layer 422, substantially dissolves the deprotected regions 426 of the mandrels 406, and substantially dissolves the deprotected regions 430 of the mandrels 418 (see FIG. 4F). In other words, the solvent may be selected such that solubilities of the protected regions 428 of the mandrels 406 and the protected regions 432 of the mandrels 418 are less than solubility of the polymer layer 422, and the solubility of the polymer layer 422 is less than solubilities of the deprotected regions 426 of the mandrels 406 and the deprotected regions 430 of the mandrels 418 (see FIG. 4F). In some embodiments, the solvent may comprise polar solvent such as standard tetramethyl ammonium hydroxide (TMAH) aqueous developer, or the like.

In some embodiments, the mandrels 434 have a width W₂₃, which is substantially same as W₂₂ (see FIG. 4D), the mandrels 436 have a width W₂₄, which is equal to W₁₉−2*D₈ (see FIGS. 4D and 4F), the mandrels 438 have a width W₂₅, which is equal to W₂₁−2*D₉ (see FIGS. 4D and 4F), the openings 442 have a width W₂₆, which is substantially same as the depth D₈ (see FIG. 4F), and the openings 444 have a width W₂₇, which is substantially same as the depth D₉ (see FIG. 4F). In some embodiments, dimensions (e.g., widths W₂₃ through W₂₇) of the patterned mask 440 may be smaller than dimensions (e.g., widths W₁₉ and W₂₀) of the mandrels 406 and the openings 408 (see FIG. 4A). This reduction in feature size is a result of the controlled acid diffusion process and can be used to achieve patterns with dimensions smaller than those directly achievable through the initial lithography process. In some embodiments, dimensions (e.g., widths W₂₃ through W₂₇) of the patterned mask 440 may be tuned by tuning the widths W₁₉ and W₂₀, and the depths D_{7,} D₈, and D₉ (see FIGS. 4A, 4C, and 4F)_{.} In one embodiment, dimensions (e.g., widths W₂₃ through W₂₇) of the patterned mask 440 may be tuned such that the widths W₂₃ through W₂₇ are equal to each other.

In FIG. 4H, a pattern defined by the patterned mask 440 is transferred to the target layer 404 (see FIG. 4G). In some embodiments, the pattern transfer may be accomplished through an etching process. The etching process selectively removes portions of the target layer 404 that are not protected by the patterned mask 440, resulting in the formation of the patterned target layer. In some embodiments, the etching process may be a dry etching technique such as reactive ion etching (RIE), plasma etching, or ion beam etching. In other embodiments, wet etching techniques may be employed. In some embodiment, the pattern transfer process may be followed by the removal of any remaining patterned mask 440. The removal can be accomplished using suitable solvents, plasma ashing techniques, or the like, leaving the patterned target layer 404 on the substrate 402.

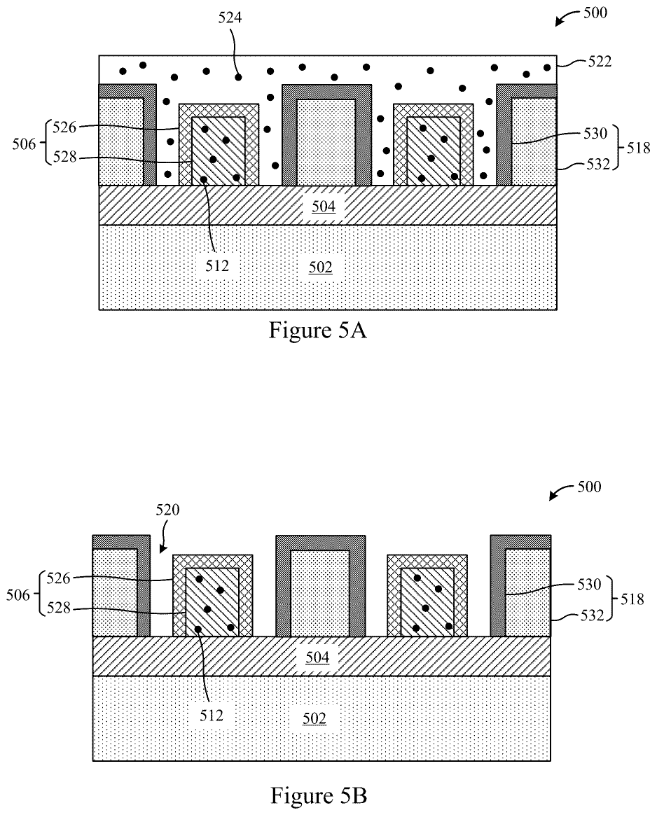

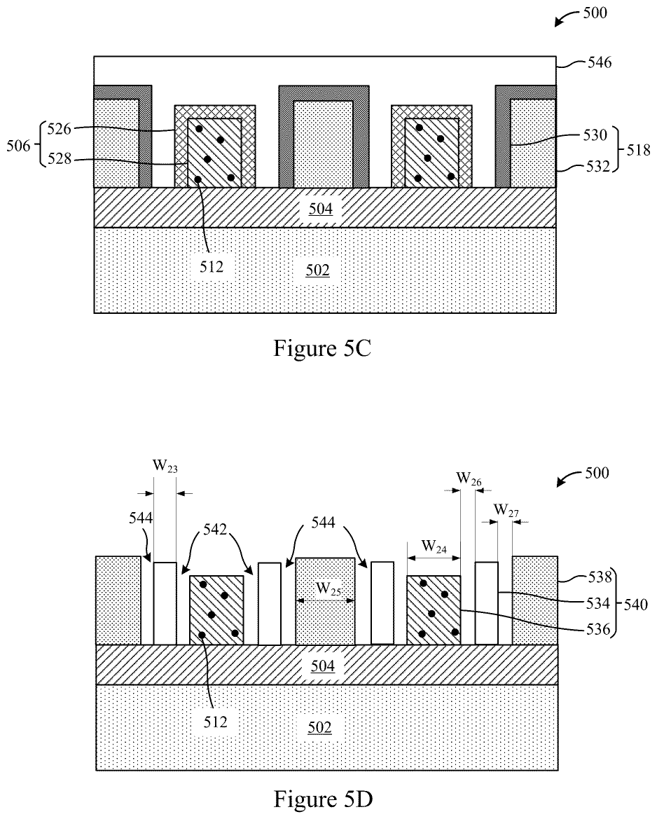

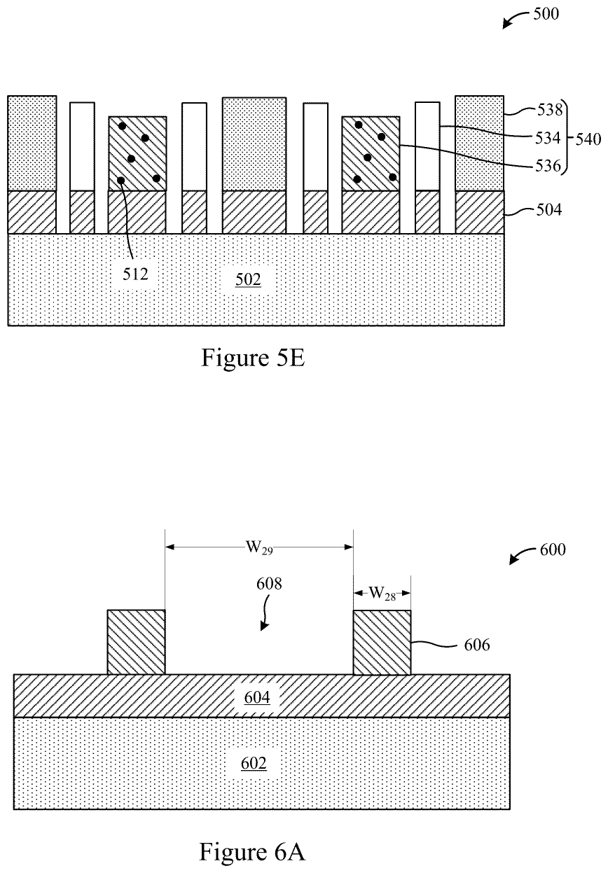

FIGS. 5A-5E illustrate cross-sectional views of intermediate stages in the manufacturing of a patterned mask over a substrate in accordance with various embodiments. Unless otherwise indicated, features 5xx of FIGS. 5A-5E may be similar to features 4xx of FIGS. 4A-4H, may be formed using materials and methods that are similar to those described above with reference to FIGS. 4A-4H, and descriptions of the similar features are not repeated herein.

In FIG. 5A, a semiconductor structure 500 is illustrated. The semiconductor structure 500 may be similar to the semiconductor structure 400 illustrated in FIG. 4F, with features 5xx being similar to features 4xx, and descriptions of the similar features are not repeated herein. In some embodiments, the semiconductor structure 500 of FIG. 5A may be formed using materials and methods that are similar to those described above with reference to FIGS. 4A-4F, and the description is not repeated herein.

In some embodiments, the semiconductor structure 500 comprises a substrate 502 and a target layer 504 over the substrate 502. The semiconductor structure 500 further comprises mandrels 506 and 518 over the target layer 504 and a polymer layer 522 over the mandrels 506 and 518. The mandrels 506 comprise deprotected regions 526 and protected regions 528. The mandrels 518 comprise deprotected regions 530 and protected regions 532. In some embodiments, a top surface of the polymer layer 522 is above top surfaces of the mandrels 506 and 518.

In FIG. 5B, the polymer layer 522 (see FIG. 5A) is selectively removed, leaving the mandrels 506 and 518 substantially intact. In some embodiments, the selective removal of the polymer layer 522 may be accomplished using a solvent that preferentially dissolves or etches the polymer layer 522 without substantially affecting the mandrels 506 and 518. The choice of the solvent depends on the specific compositions of the mandrels 506 and 518, and the polymer layer 522. In some embodiments, the solvent may comprise isoamyl ether, n-pentanol, or similar non-polar solvents as the majority composition or a combination thereof, or the like.

In FIG. 5C, a polymer layer 546 is deposited over the mandrels 506 and 518. The polymer layer 546 may overfill the openings 520 (see FIG. 5B) such that a top surface of the polymer layer 546 is above top surfaces of the mandrels 506 and 518. In some embodiments, the polymer layer 546 may comprise a polymer material with majority backbone such as t-butyl styrene or n-butyl methacrylate with additional minority components such as methyl methacrylate or methacrylic acid or a combination thereof, or the like. In some embodiments, the polymer layer 546 may be free from free acid and agent-generating ingredients.

In some embodiments, the polymer layer 546 may be deposited using techniques such as spin coating, CVD, ALD, a combination thereof, or the like. The choice of deposition technique may depend on factors such as the desired thickness of the polymer layer 546, its composition, and compatibility with the mandrels 506 and 518. For example, the polymer layer 546 may be deposited using a solvent that does not dissolve the deprotected regions 526 and the protected regions 528 of the mandrels 506 and the deprotected regions 530 and the protected regions 532 of the mandrels 518. In some embodiments, the solvent may comprise isoamyl ether, n-pentanol, or similar non-polar solvents as the majority composition, or a combination thereof, or the like.

In some embodiments, after depositing the polymer layer 546, a post-deposition bake process may be performed on the polymer layer 546 to remove any solvents and stabilize the polymer layer 546. The post-deposition bake process may be performed at a process temperature in a range from 75 °C to 100 °C for a process time in a range from 30 to 180 seconds.

In FIG. 5D, a portion of the polymer layer 546 (see FIG. 5C) is removed to expose the deprotected regions 526 of the mandrels 506 and the deprotected regions 530 of the mandrels 518, such that remaining portions of the polymer layer 546 form mandrels 534. Furthermore, the deprotected regions 526 of the mandrels 506 (see FIG. 5C) are removed to form openings 542 and the deprotected regions 530 of the mandrels 518 (see FIG. 5C) are removed to form openings 544. The openings 542 and 544 expose the target layer 504. The protected regions 528 of the mandrels 506 (see FIG. 5C) form mandrels 536 on the target layer 504 and the protected regions 532 of the mandrels 518 (see FIG. 5C) form mandrels 538 on the target layer 504. The mandrels 534, 536 and 538 form a patterned mask 540 on the target layer 504.

In some embodiments, the removal process may be performed using a suitable solvent. The solvent may be selected such that it does not substantially dissolve the protected regions 528 of the mandrels 506, does not substantially dissolve the protected regions 532 of the mandrels 518, moderately dissolves the polymer layer 546, substantially dissolves the deprotected regions 526 of the mandrels 506, and substantially dissolves the deprotected regions 530 of the mandrels 518 (see FIG. 5C). In other words, the solvent may be selected such that solubilities of the protected regions 528 of the mandrels 506 and the protected regions 532 of the mandrels 518 are less than solubility of the polymer layer 546, and the solubility of the polymer layer 546 is less than solubilities of the deprotected regions 526 of the mandrels 506 and the deprotected regions 530 of the mandrels 518 (see FIG. 5C). In some embodiments, the solvent may comprise a polar solvent such as tetramethyl ammonium hydroxide (TMAH) aqueous developer, or the like.

In FIG. 5E, a pattern defined by the patterned mask 540 is transferred to the target layer 504. In some embodiments, the pattern transfer may be accomplished through an etching process. The etching process selectively removes portions of the target layer 504 that are not protected by the patterned mask 540, resulting in the formation of the patterned target layer. In some embodiments, the etching process may be a dry etching technique such as reactive ion etching (RIE), plasma etching, or ion beam etching. In other embodiments, wet etching techniques may be employed. In some embodiment, the pattern transfer process may be followed by the removal of any remaining patterned mask 540. The removal can be accomplished using suitable solvents, plasma ashing techniques, or the like, leaving the patterned target layer 504 on the substrate 502.

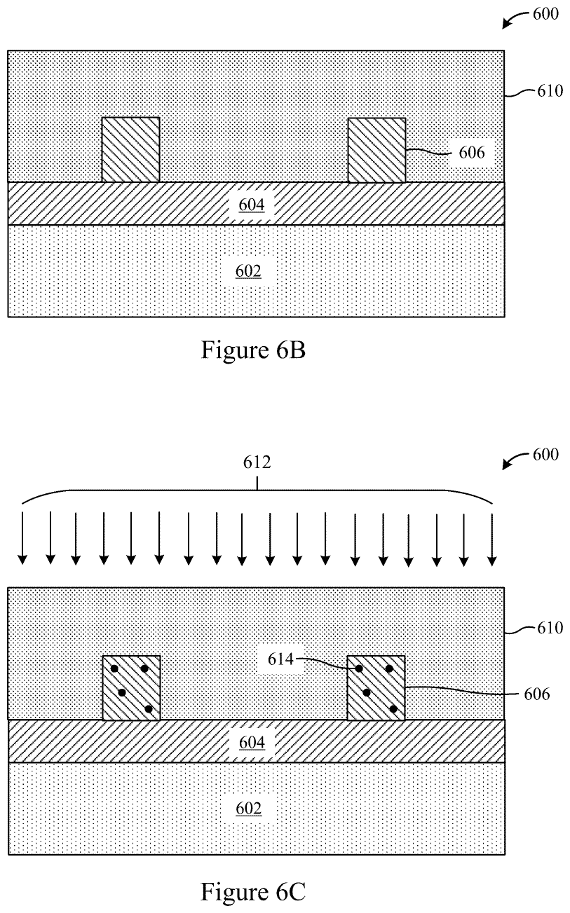

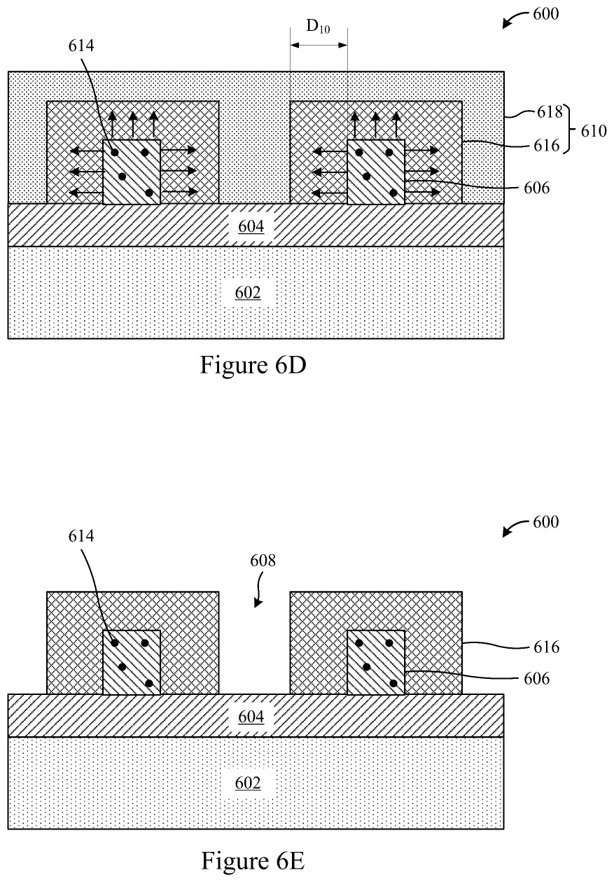

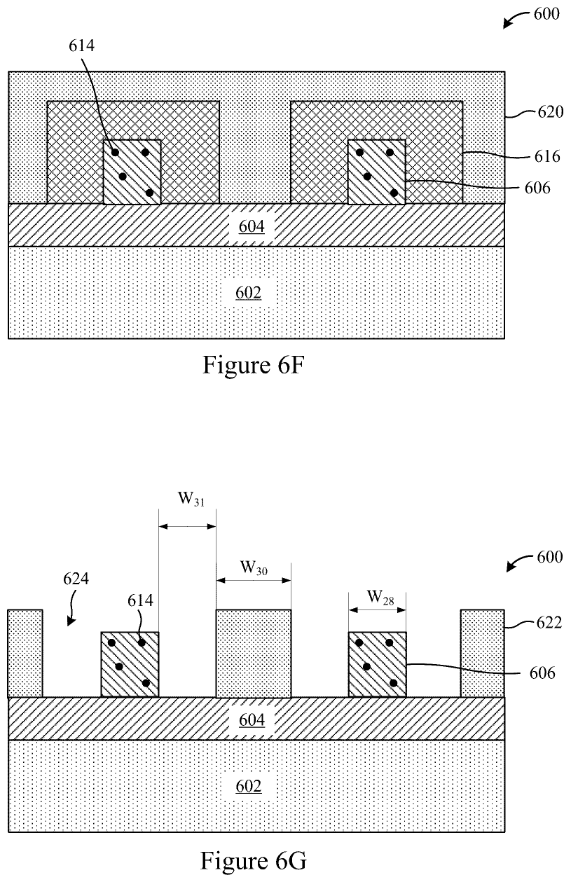

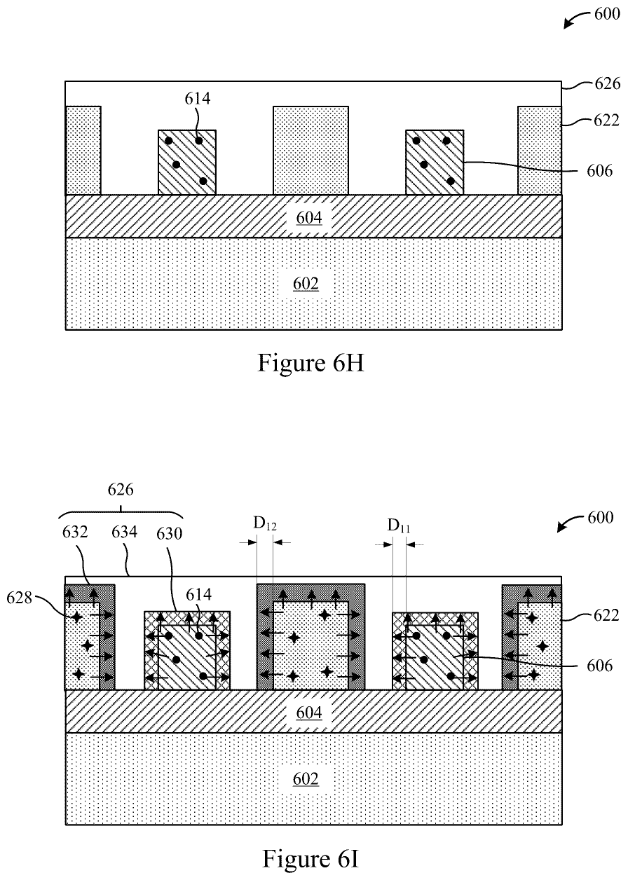

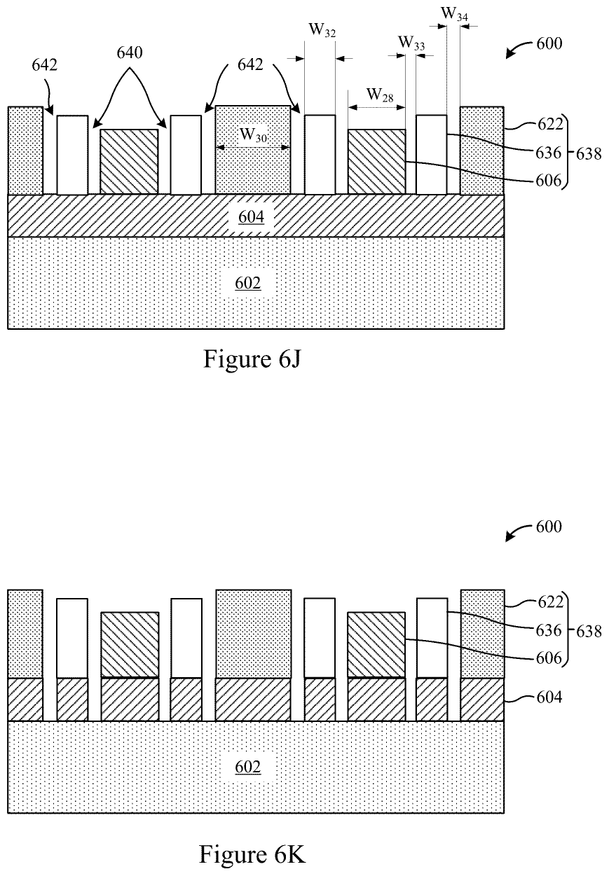

FIGS. 6A-6K illustrate cross-sectional views of intermediate stages in the manufacturing of a patterned mask over a substrate in accordance with various embodiments. In FIG. 6A, a semiconductor structure 600 is illustrated. The semiconductor structure 600 may include a substrate 602. The substrate 602 may be similar to the substrate 102 described above with reference to FIG. 1A, and the description is not repeated herein. In some embodiments, a target layer 604 is formed over the substrate 602. The target layer 604 represents a layer that will be subsequently patterned. The target layer 604 may be formed using similar materials and methods as the target layer 104 described above with reference to FIG. 1A, and the description is not repeated herein.

In some embodiments, mandrels 606 are formed over the target layer 604. The mandrels 606 may be separated by openings 608. The openings 608 define areas where the underlying target layer 604 is exposed. The mandrels 606 may have a width W₂₈ and the openings 608 may have a width W₂₉. The width W₂₈ may be same as or different from the width W₂₉. In some embodiments, the mandrels 606 may be formed using similar materials and methods as the mandrels 106 described above with reference to FIG. 1A, and the description is not repeated herein. In some embodiments, the mandrels 606 may comprise a PAG.

In FIG. 6B, a polymer layer 610 is deposited over the mandrels 606. The polymer layer 610 may be also referred to as a reversible overcoat layer. The polymer layer 610 may overfill the openings 608 (see FIG. 6A) such that a top surface of the polymer layer 610 is above top surfaces of the mandrels 606. In some embodiments, the polymer layer 610 may comprise a polymer material with majority backbone such as styrene, hydroxy styrene or n-butyl methacrylate with additional minority components composed of low activation energy acid labile pendant groups such as 1-Ethylcyclopentyl methacrylate or an acetal moiety a combination thereof, or the like. In some embodiments, the polymer layer 610 may be free from free acid and agent-generating ingredients.

In some embodiments, the polymer layer 610 may be deposited using techniques such as spin coating, CVD, ALD, a combination thereof, or the like. The choice of deposition technique may depend on factors such as the desired thickness of the polymer layer 610, its composition, and compatibility with the mandrels 606. For example, the polymer layer 610 may be deposited using a solvent that does not dissolve the mandrels 606. In some embodiments, the solvent may comprise methyl isobutyl carbinol (MIBC), isoamyl ether (IAE), Isobutyl Isobutyrate (IBIB) or a combination thereof, or the like.

In some embodiments, after depositing the polymer layer 610, a post-deposition bake process may be performed on the polymer layer 610 to remove any solvents and stabilize the polymer layer 610. The post-deposition bake process may be performed at a process temperature in a range from 75 °C to 100 °C for a process time in a range from 30 to 180 seconds.

In FIG. 6C, the mandrels 606 are exposed to a radiation 612 (e.g., actinic radiation) though the polymer layer 610. In some embodiments, when the mandrels 606 comprise PAG, the radiation 612 generates free acid 614 in the mandrels 606. In some embodiment, the free acid 614 may deprotect the mandrels 606. In other words, the free acid 614 may alter solubility of the mandrels 606.

In FIG. 6D, a thermal treatment is performed in the structure of FIG. 6C. In some embodiments, the thermal treatment may be performed at a process temperature in a range from 75 °C to 100 °C for a process time in a range from 30 to 180 seconds. In some embodiments, the thermal treatment may cause the free acid 614 to diffuse (as shown by arrows in FIG. 6D) from the mandrels 606 into the polymer layer 610. The diffused free acid 614 reacts with the material of the polymer layer 610 and creates deprotected regions 616 within the polymer layer 610. A remaining region of the polymer layer 610 forms a protected region 618 of the polymer layer 610. The deprotected regions 616 of the polymer layer 610 may have different chemical properties (e.g., solubility in various solvents) compared to the protected region 618 of the polymer layer 610.

The free acid 614 may diffuse into to the polymer layer 610 to a depth D₁₀. The depth D₁₀ may be in a range from 15 to 40 nanometers. The depth D₁₀ may be controlled by tuning a concentration of the free acid 614, a diffusion coefficient of the free acid 614 in the polymer layer 610, a process temperature of the thermal treatment, and/or a process time of the thermal treatment.

In FIG. 6E, the protected regions 618 of the polymer layer 610 (see FIG. 6D) is selectively removed, leaving the mandrels 606 and the deprotected regions 616 of the polymer layer 610 substantially intact. In some embodiments, the selective removal of the protected regions 618 of the polymer layer 610 may be accomplished using a solvent that preferentially dissolves or etches the protected regions 618 of the polymer layer 610 without substantially affecting the mandrels 606 and the deprotected regions 616 of the polymer layer 610. The choice of the solvent depends on the specific compositions of the mandrels 606 and the polymer layer 610. In some embodiments, the solvent may comprise methyl isobutyl carbinol (MIBC), isoamyl ether (IAE), Isobutyl Isobutyrate (IBIB), a combination thereof, or the like.

In FIG. 6F, a polymer layer 620 is deposited over the mandrels 606 and the deprotected regions 616 of the polymer layer 610 (see FIG. 6D). The polymer layer 620 may overfill the openings 608 (see FIG. 6E) such that a top surface of the polymer layer 620 is above top surfaces of the deprotected regions 616. In some embodiments, the polymer layer 620 may comprise a polymer material with majority backbone such as t-butyl styrene or n-butyl methacrylate with additional minority components composed of low activation energy acid labile pendant groups such as 1-Ethylcyclopentyl methacrylate or an acetal moiety, a combination thereof, or the like. In some embodiments, the polymer layer 620 may comprise free acid or an agent-generating ingredient such as TAG or PAG.

In some embodiments, the polymer layer 620 may be deposited using techniques such as spin coating, CVD, ALD, a combination thereof, or the like. The choice of deposition technique may depend on factors such as the desired thickness of the polymer layer 620, its composition, and compatibility with the mandrels 606 and the deprotected regions 616. For example, the polymer layer 620 may be deposited using a solvent that does not dissolve the mandrels 606 and the deprotected regions 616. In some embodiments, the solvent may comprise methyl isobutyl carbinol (MIBC), isoamyl ether (IAE), Isobutyl Isobutyrate (IBIB), a combination thereof, or the like.

In FIG. 6G, a portion of the polymer layer 620 (see FIG. 6F) is removed to expose the deprotected regions 616, such that remaining portions of the polymer layer 620 form mandrels 622 on the target layer 604. Furthermore, the deprotected regions 616 (see FIG. 6F) are removed to form openings 624, which expose the target layer 604. In some embodiments, the mandrels 622 have a width W₃₀, which is equal to W₂₉−2*D₁₀ (see FIGS. 6A and 6D) and the openings 624 have a width W₃₁, which is substantially same as the depth D₁₀ (see FIG. 6D).

In some embodiments, the removal process may be performed using a suitable solvent. The solvent may be selected such that it does not substantially dissolve the mandrels 606, moderately dissolves the polymer layer 620, and substantially dissolves the deprotected regions 616 (see FIG. 6F). In other words, the solvent may be selected such that solubility of the mandrels 606 is less than solubility of the polymer layer 620, and the solubility of the polymer layer 620 is less than solubility of the deprotected regions 616 (see FIG. 6F). In some embodiments, the solvent may comprise a polar solvent such as tetramethyl ammonium hydroxide (TMAH) aqueous developer, or the like.

In FIG. 6H, a polymer layer 626 is deposited over the mandrels 606 and 622. The polymer layer 626 may overfill the openings 624 (see FIG. 6G), such that a top surface of the polymer layer 626 is above top surfaces of the mandrels 606 and 622. In some embodiments, the polymer layer 626 may comprise a polymer material with majority backbone such as t-butyl styrene or n-butyl methacrylate with additional minority components composed of low activation energy acid labile pendant groups such as 1-Ethylcyclopentyl methacrylate or an acetal moiety, a combination thereof, or the like. In some embodiments, the polymer layer 626 may be free from free acid and agent-generating ingredients.

In some embodiments, the polymer layer 626 may be deposited using techniques such as spin coating, CVD, ALD, a combination thereof, or the like. The choice of deposition technique may depend on factors such as the desired thickness of the polymer layer 626, its composition, and compatibility with the mandrels 606 and 622. For example, the polymer layer 626 may be deposited using a solvent that does not dissolve the mandrels 606 and 622. In some embodiments, the solvent may comprise isoamyl ether, n-pentanol, or similar non-polar solvents as the majority composition, a combination thereof, or the like.

In FIG. 6I, a thermal treatment may be performed on the structure of FIG. 6H. The thermal treatment may be a single thermal treatment or may comprise multiple thermal treatments performed at different process parameters (e.g., process temperature and time). In some embodiments, the thermal treatment may comprise a post-deposition bake process performed to remove any solvents and stabilize the polymer layer 626. The post-deposition bake process may be performed at a process temperature in a range from 75 °C to 100 °C for a process time in a range from 30 to 180 seconds.

In some embodiments when the mandrel 622 comprises a TAG that has an activation temperature that is less than the process temperature of the post-deposition bake process, free acid 628 is generated in the mandrel 622. In other embodiments when the mandrel 622 comprises a TAG that has an activation temperature that is greater than the process temperature of the post-deposition bake process, no free acid is generated in the mandrel 622.

In some embodiments, the post-deposition bake process may further cause the free acids 614 and 628 to diffuse (as shown by arrows in FIG. 6I) from the mandrels 606 and 622, respectively, into the polymer layer 626. The diffused free acid 614 reacts with the material of the polymer layer 626 and creates deprotected regions 630 within the polymer layer 626. The diffused free acid 628 reacts with the material of the polymer layer 626 and creates deprotected regions 632 within the polymer layer 626. A remaining region of the polymer layer 626 forms a protected region 634 of the polymer layer 626. The deprotected regions 630 and 632 of the polymer layer 626 may have different chemical properties (e.g., solubility in various solvents) compared to the protected region 634 of the polymer layer 626.

In some embodiments when the mandrel 622 comprises a TAG that has an activation temperature that is greater than the process temperature of the post-deposition bake process, an additional thermal treatment may be performed on the structure of FIG. 6H after the post-deposition bake process to generate the free acid 628 in the mandrel 622. The additional thermal treatment may be performed at a process temperature that is greater than the activation temperature of the TAG. In some embodiments, the additional thermal treatment may be performed at a process temperature in a range from 100 °C to 150 °C for a process time in a range from 15 to 120 seconds.

In some embodiments, the additional thermal treatment may further cause the free acids 614 and 628 to diffuse (as shown by arrows in FIG. 6I) from the mandrels 606 and 622, respectively, into the polymer layer 626. The diffused free acid 614 reacts with the material of the polymer layer 626 and creates deprotected regions 630 within the polymer layer 626. The diffused free acid 628 reacts with the material of the polymer layer 626 and creates deprotected regions 632 within the polymer layer 626. A remaining region of the polymer layer 626 forms a protected region 634 of the polymer layer 626.

The free acid 614 may diffuse into to the polymer layer 626 to a depth D₁₁. The free acid 628 may diffuse into to the polymer layer 626 to a depth D₁₂. In some embodiments, the depth D₁₁ may be same as the depth D₁₂. In other embodiments, the depth D₁₁ may be different from the depth D₁₂. The depth D₁₁ may be in a range from 5 to 25 nanometers. The depth D₁₂ may be in a range from 5 to 25 nanometers. The depth D₁₁ may be controlled by tuning a concentration of the free acid 614, a diffusion coefficient of the free acid 614 in the polymer layer 626, a process temperature of the thermal treatment, and/or a process time of the thermal treatment. The depth D₁₂ may be controlled by tuning a concentration of the free acid 628, a diffusion coefficient of the free acid 628 in the polymer layer 626, a process temperature of the thermal treatment, and/or a process time of the thermal treatment.

In FIG. 6J, a portion of the protected region 634 of the polymer layer 626 is removed to expose the deprotected regions 630 of the polymer layer 626 and deprotected regions 632 of the polymer layer 626, such that remaining portions of the protected region 634 form mandrels 636 (see FIG. 6I). Furthermore, the deprotected regions 630 of the polymer layer 626 (see FIG. 6I) are removed to form openings 640 and the deprotected regions 632 of the polymer layer 626 (see FIG. 6I) are removed to form openings 642. The openings 640 and 642 expose the target layer 604. The mandrels 606, 622 and 636 form a patterned mask 638 on the target layer 604.

In some embodiments, the removal process may be performed using a suitable solvent. The solvent may be selected such that it does not substantially dissolve the mandrels 606 and 622, moderately dissolves the protected region 634 of the polymer layer 626, and substantially dissolves the deprotected regions 630 and 632 of the polymer layer 626 (see FIG. 6I). In other words, the solvent may be selected such that solubilities of the mandrels 606 and 622 are less than solubility of the protected region 634 of the polymer layer 626, and the solubility of the protected region 634 of the polymer layer 626 is less than solubilities of deprotected regions 630 and 632 of the polymer layer 626 (see FIG. 6I). In some embodiments, the solvent may comprise a polar solvent such as standard tetramethyl ammonium hydroxide (TMAH) aqueous developer, or the like.

In some embodiments, the mandrels 636 have a width W₃₂, which is equal to W₃₁−D₁₁−D₁₂ (see FIGS. 6G and 6I), the openings 640 have a width W₃₃, which is substantially same as the depth D₁₁ (see FIG. 6I), and the openings 642 have a width W₃₄, which is substantially same as the depth D₁₂ (see FIG. 6I).

In some embodiments, dimensions (e.g., widths W₃₀ and W₃₂ through W₃₄) of the patterned mask 638 may be smaller than dimensions (e.g., width W₂₉) of the openings 608 (see FIG. 6A). This reduction in feature size is a result of the controlled acid diffusion process and can be used to achieve patterns with dimensions smaller than those directly achievable through the initial lithography process. In some embodiments, dimensions (e.g., W₂₈, W₃₀, and W₃₂ through W₃₄) of the patterned mask 638 may be tuned by tuning the widths W₂₈ and W₂₉, and the depths D_{10,} D₁₁, and D₁₂ (see FIGS. 6A, 6B, and 6I)_{.} In one embodiment, dimensions (e.g., W₂₈, W₃₀, and W₃₂ through W₃₄) of the patterned mask 638 may be tuned such that the widths W₂₈, W₃₀, and W₃₂ through W₃₄ are equal to each other.

In FIG. 6K, a pattern defined by the patterned mask 638 is transferred to the target layer 604. In some embodiments, the pattern transfer may be accomplished through an etching process. The etching process selectively removes portions of the target layer 604 that are not protected by the patterned mask 638, resulting in the formation of the patterned target layer. In some embodiments, the etching process may be a dry etching technique such as reactive ion etching (RIE), plasma etching, or ion beam etching. In other embodiments, wet etching techniques may be employed. In some embodiment, the pattern transfer process may be followed by the removal of any remaining patterned mask 638. The removal can be accomplished using suitable solvents, plasma ashing techniques, or the like, leaving the patterned target layer 604 on the substrate 602.

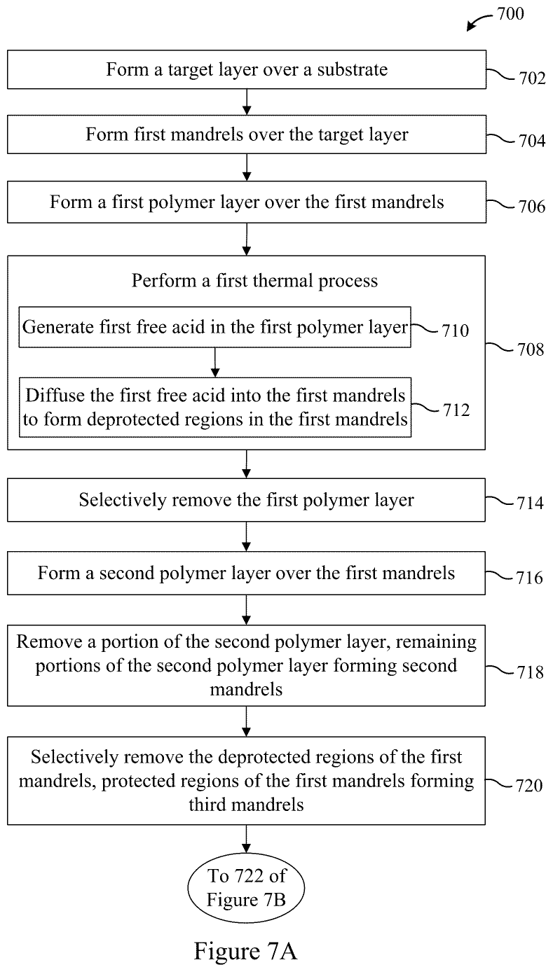

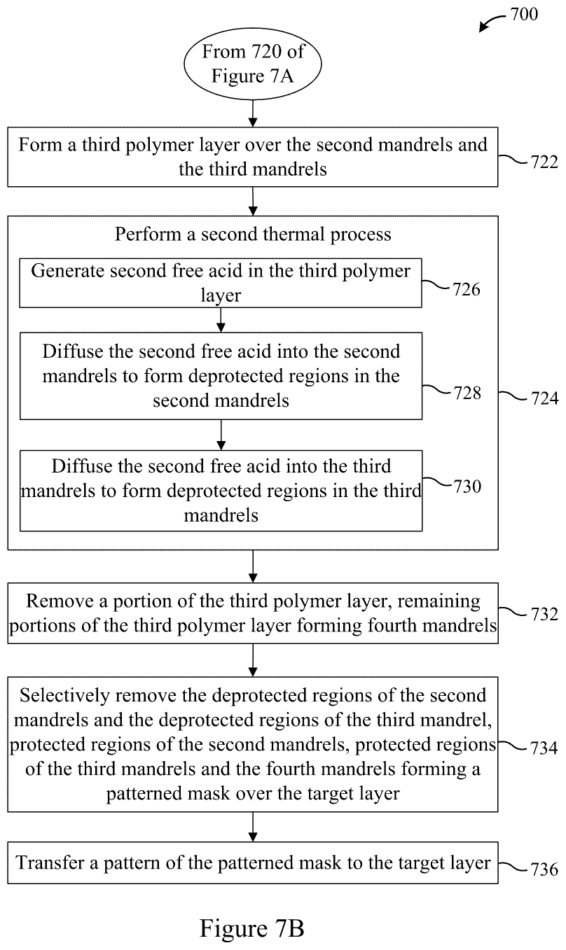

FIGS. 7A and 7B illustrate a flow diagram of a method 700 for forming a patterned mask over a substrate in accordance with various embodiments. In step 702, a target layer (e.g., target layer 104) is formed over a substrate (e.g., substrate 102), as described above with reference to FIG. 1A. In step 704, first mandrels (e.g., mandrels 106) are formed over the target layer (e.g., target layer 104), as described above with reference to FIG. 1A. In step 706, a first polymer layer (e.g., polymer layer 110) is formed over the first mandrels (e.g., mandrels 106), as described above with reference to FIG. 1B.

In step 708, a first thermal process is performed, as described above with reference to FIG. 1C. In some embodiments, step 708 comprises steps 710 and 712. In step 710, first free acid (e.g., free acid 112) is generated in the first polymer layer (e.g., polymer layer 110), as described above with reference to FIG. 1C. In step 712, the first free acid (e.g., free acid 112) is diffused into the first mandrels (e.g., mandrels 106) to form deprotected regions (e.g., deprotected regions 114) in the first mandrels (e.g., mandrels 106), as described above with reference to FIG. 1C.

In step 714, the first polymer layer (e.g., polymer layer 110) is selectively removed, as described above with reference to FIG. 1D. In step 716, a second polymer layer (e.g., polymer layer 118) is formed over the first mandrels (e.g., mandrels 106), as described above with reference to FIG. 1E. In step 718, a portion of the second polymer layer (e.g., polymer layer 118) is removed to expose the deprotected regions (e.g., deprotected regions 114) of the first mandrels (e.g., mandrels 106), such that remaining portions of the second polymer layer (e.g., polymer layer 118) form second mandrels (e.g., mandrels 120), as described above with reference to FIG. 1F. In step 720, the deprotected regions (e.g., deprotected regions 114) of the first mandrels (e.g., mandrels 106) are selectively removed such that protected regions (e.g., protected regions 116) of the first mandrels (e.g., mandrels 106) form third mandrels (e.g., mandrels 124), as described above with reference to FIG. 1F.

In step 722, a third polymer layer (e.g., polymer layer 126) is formed over the second mandrels (e.g., mandrels 120) and the third mandrels (e.g., mandrels 124), as described above with reference to FIG. 1G. In step 724, a second thermal process is performed, as described above with reference to FIG. 1H. In some embodiments, step 724 comprises steps 726, 728, and 730. In step 726, second free acid (e.g., free acid 128) is generated in the third polymer layer (e.g., polymer layer 126), as described above with reference to FIG. 1H. In step 728, the second free acid (e.g., free acid 128) is diffused into the second mandrels (e.g., mandrels 120) to form deprotected regions (e.g., deprotected regions 134) in the second mandrels (e.g., mandrels 120), as described above with reference to FIG. 1H. In step 730, the second free acid (e.g., free acid 128) is diffused into the third mandrels (e.g., mandrels 124) to form deprotected regions (e.g., deprotected regions 130) in the third mandrels (e.g., mandrels 124), as described above with reference to FIG. 1H.

In step 732, a portion of the third polymer layer (e.g., polymer layer 126) is removed to expose the deprotected regions (e.g., deprotected regions 134) of the second mandrels (e.g., mandrels 120) and the deprotected regions (e.g., deprotected regions 130) of the third mandrels (e.g., mandrels 124), such that remaining portions of the third polymer layer (e.g., polymer layer 126) form fourth mandrels (e.g., mandrels 138), as described above with reference to FIG. 1I. In step 734, the deprotected regions (e.g., deprotected regions 134) of the second mandrels (e.g., mandrels 120) and the deprotected regions (e.g., deprotected regions 130) of the third mandrels (e.g., mandrels 124) are selectively removed, such that protected regions (e.g., protected regions 136) of the second mandrels (e.g., mandrels 120), protected regions (e.g., protected regions 132) of the third mandrels (e.g., mandrels 124), and the fourth mandrels (e.g., mandrels 138) form a patterned mask (e.g., patterned mask 144) over the target layer (e.g., target layer 104), as described above with reference to FIG. 1I. In step 736, a pattern of the patterned mask (e.g., patterned mask 144) is transferred to the target layer (e.g., target layer 104), as described above with reference to FIG. 1J.

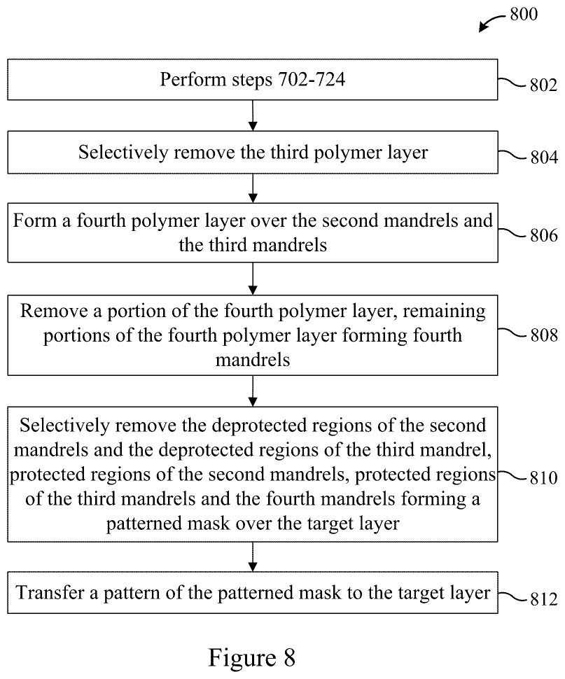

FIG. 8 illustrates a flow diagram of a method 800 for forming a patterned mask over a substrate in accordance with various embodiments. Method 800 starts with step 802. In some embodiments, step 802 comprises steps 702-724 as described above with reference to FIGS. 7A and 7B, and the description is not repeated herein. In step 804, the third polymer layer (e.g., polymer layer 226) is selectively removed, as described above with reference to FIGS. 2A and 2B. In step 806, a fourth polymer layer (e.g., polymer layer 250) is formed over the second mandrels (e.g., mandrels 220) and the third mandrels (e.g., mandrels 224), as described above with reference to FIG. 2C.

In step 808, a portion of the fourth polymer layer (e.g., polymer layer 250) is removed to expose the deprotected regions (e.g., deprotected regions 234) of the second mandrels (e.g., mandrels 220) and the deprotected regions (e.g., deprotected regions 230) of the third mandrels (e.g., mandrels 224), such that remaining portions of the fourth polymer layer (e.g., polymer layer 250) form fourth mandrels (e.g., mandrels 238), as described above with reference to FIG. 2D.

In step 810, the deprotected regions (e.g., deprotected regions 234) of the second mandrels (e.g., mandrels 220) and the deprotected regions (e.g., deprotected regions 230) of the third mandrels (e.g., mandrels 224) are selectively removed, such that protected regions (e.g., protected regions 236) of the second mandrels (e.g., mandrels 220), protected regions (e.g., protected regions 232) of the third mandrels (e.g., mandrels 224), and the fourth mandrels (e.g., mandrels 238) form a patterned mask (e.g., patterned mask 244) over the target layer (e.g., target layer 204), as described above with reference to FIG. 2D. In step 812, a pattern of the patterned mask (e.g., patterned mask 244) is transferred to the target layer (e.g., target layer 204), as described above with reference to FIG. 2E.

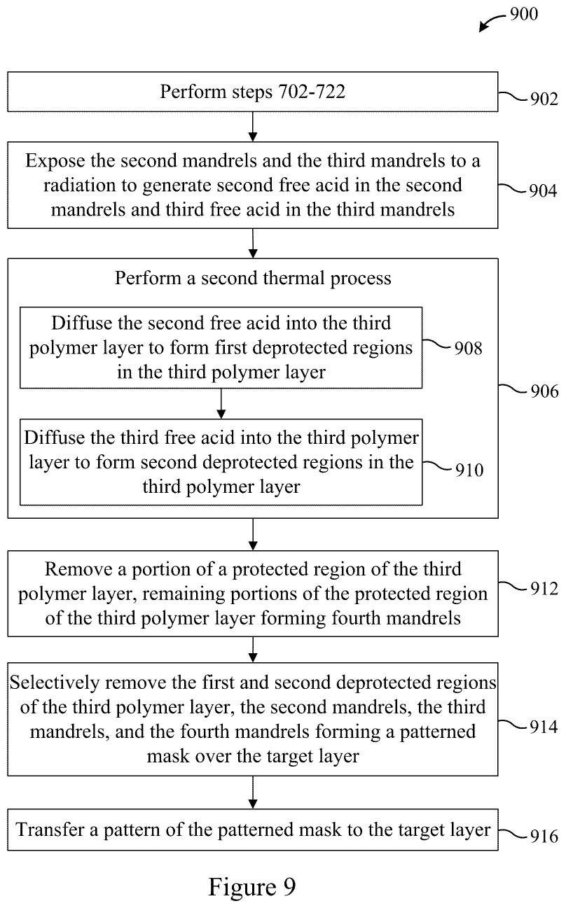

FIG. 9 illustrates a flow diagram of a method 900 for forming a patterned mask over a substrate in accordance with various embodiments. Method 900 starts with step 902. In some embodiments, step 902 comprises steps 702-722 as described above with reference to FIGS. 7A and 7B, and the description is not repeated herein. In step 904, the second mandrels (e.g., mandrels 320) and the third mandrels (e.g., mandrels 324) are exposed to a radiation (e.g., radiation 328) to generate second free acid (e.g., free acid 330) in the second mandrels (e.g., mandrels 320) and third free acid (e.g., free acid 332) in the third mandrels (e.g., mandrels 324), as described above with reference to FIG. 3H.

In step 906, a second thermal process is performed, as described above with reference to FIG. 3I. In some embodiments, step 906 comprises steps 908 and 910. In step 908, the second free acid (e.g., free acid 330) is diffused into the third polymer layer (e.g., polymer layer 326) to form first deprotected regions (e.g., deprotected regions 334) in the third polymer layer (e.g., polymer layer 326), as described above with reference to FIG. 3I. In step 910, the third free acid (e.g., free acid 332) is diffused into the third polymer layer (e.g., polymer layer 326) to form second deprotected regions (e.g., deprotected regions 336) in the third polymer layer (e.g., polymer layer 326), as described above with reference to FIG. 3I.

In step 912, a portion of a protected region (e.g., protected region 338) of the third polymer layer (e.g., polymer layer 326) is removed to expose the first deprotected regions (e.g., deprotected regions 334) and the second deprotected regions (e.g., deprotected regions 336) of the third polymer layer (e.g., polymer layer 326), such that remaining portions of the protected region (e.g., protected region 338) of the third polymer layer (e.g., polymer layer 326) form fourth mandrels (e.g., mandrels 340), as described above with reference to FIG. 3J.

In step 914, the first deprotected regions (e.g., deprotected regions 334) and the second deprotected regions (e.g., deprotected regions 336) of the third polymer layer (e.g., polymer layer 326) are selectively removed, such that the second mandrels (e.g., mandrels 320), the third mandrels (e.g., mandrels 324), and the fourth mandrels (e.g., mandrels 340) form a patterned mask (e.g., patterned mask 342) over the target layer (e.g., target layer 304), as described above with reference to FIG. 3J. In step 916, a pattern of the patterned mask (e.g., patterned mask 342) is transferred to the target layer (e.g., target layer 304), as described above with reference to FIG. 3K.

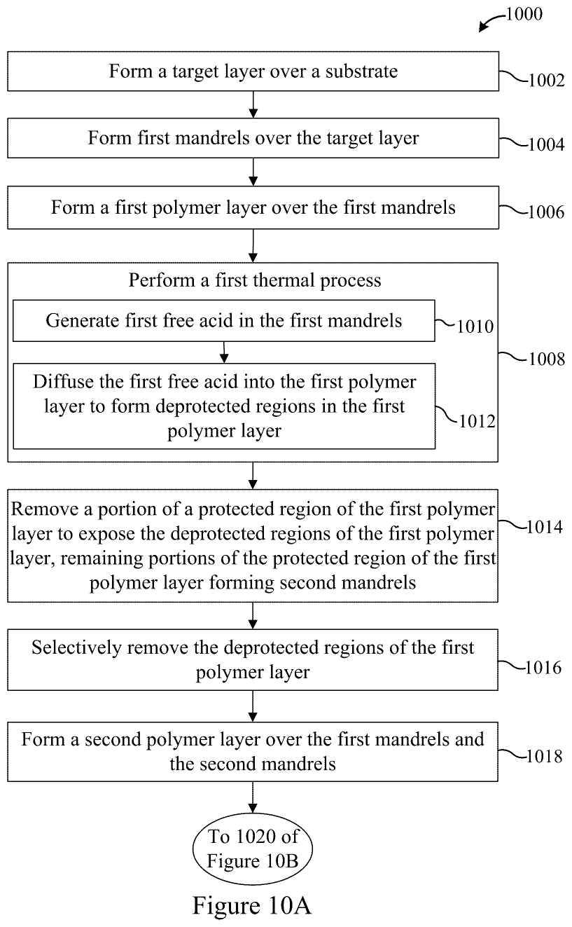

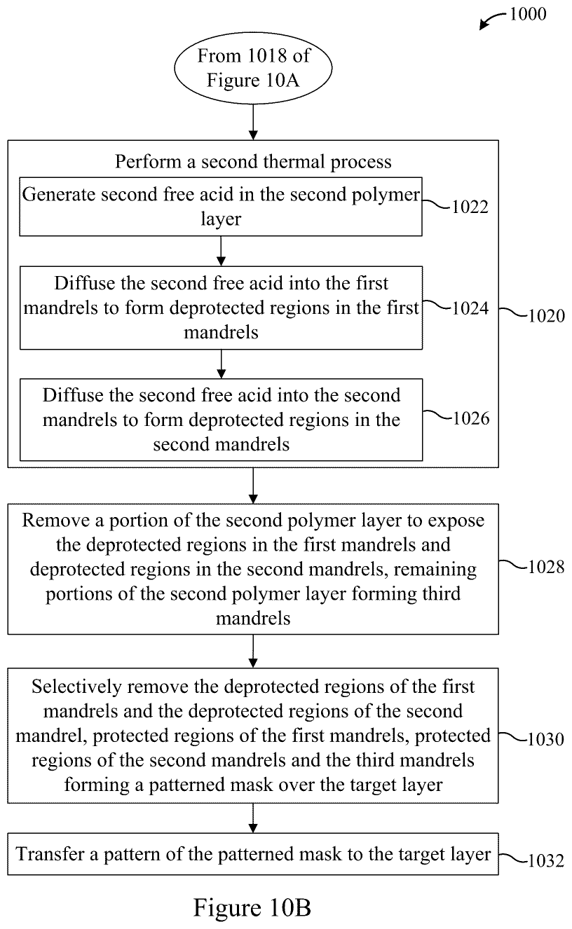

FIGS. 10A and 10B illustrate a flow diagram of a method 1000 for forming a patterned mask over a substrate in accordance with various embodiments. In step 1002, a target layer (e.g., target layer 404) is formed over a substrate (e.g., substrate 402), as described above with reference to FIG. 4A. In step 1004, first mandrels (e.g., mandrels 406) are formed over the target layer (e.g., target layer 404), as described above with reference to FIG. 4A. In step 1006, a first polymer layer (e.g., polymer layer 410) is formed over the first mandrels (e.g., mandrels 406), as described above with reference to FIG. 4B.

In step 1008, a first thermal process is performed, as described above with reference to FIG. 4C. In some embodiments, step 1008 comprises steps 1010 and 1012. In step 1010, first free acid (e.g., free acid 412) is generated in the first mandrels (e.g., mandrels 406), as described above with reference to FIG. 4C. In step 1012, the first free acid (e.g., free acid 412) is diffused into the first polymer layer (e.g., polymer layer 410) to form deprotected regions (e.g., deprotected regions 414) in the first polymer layer (e.g., polymer layer 410), as described above with reference to FIG. 4C.

In step 1014, a portion of a protected region (e.g., protected region 416) of the first polymer layer (e.g., polymer layer 410) is removed to expose the deprotected regions (e.g., deprotected regions 414) of the first polymer layer (e.g., polymer layer 410), such that remaining portions of the protected region (e.g., protected region 416) of the first polymer layer (e.g., polymer layer 410) form second mandrels (e.g., mandrels 418), as described above with reference to FIG. 4D. In step 1016, the deprotected regions (e.g., deprotected regions 414) of the first polymer layer (e.g., polymer layer 410) are selectively removed, as described above with reference to FIG. 4D.

In step 1018, a second polymer layer (e.g., polymer layer 422) is formed over the first mandrels (e.g., mandrels 406) and the second (e.g., mandrels 418), as described above with reference to FIG. 4E. In step 1020, a second thermal process is performed, as described above with reference to FIG. 4F. In some embodiments, step 1020 comprises steps 1022, 1024, and 1026. In step 1022, second free acid (e.g., free acid 424) is generated in the second polymer layer (e.g., polymer layer 422), as described above with reference to FIG. 4F. In step 1024, the second free acid (e.g., free acid 424) is diffused into the first mandrels (e.g., mandrels 406) to form deprotected regions (e.g., deprotected regions 426) in the first mandrels (e.g., mandrels 406), as described above with reference to FIG. 4F. In step 1026, the second free acid (e.g., free acid 424) is diffused into the second mandrels (e.g., mandrels 418) to form deprotected regions (e.g., deprotected regions 430) in the second mandrels (e.g., mandrels 418), as described above with reference to FIG. 4F.

In step 1028, a portion of the second polymer layer (e.g., polymer layer 422) is removed to expose the deprotected regions (e.g., deprotected regions 426) of the first mandrels (e.g., mandrels 406) and the deprotected regions (e.g., deprotected regions 430) of the second mandrels (e.g., mandrels 418), such that remaining portions of the second polymer layer (e.g., polymer layer 422) form third mandrels (e.g., mandrels 434), as described above with reference to FIG. 4G. In step 1030, the deprotected regions (e.g., deprotected regions 426) of the first mandrels (e.g., mandrels 406) and the deprotected regions (e.g., deprotected regions 430) of the second mandrels (e.g., mandrels 418) are selectively removed, such that protected regions (e.g., protected regions 428) of the first mandrels (e.g., mandrels 406), protected regions (e.g., protected regions 432) of the second mandrels (e.g., mandrels 418), and the third mandrels (e.g., mandrels 434) form a patterned mask (e.g., patterned mask 440) over the target layer (e.g., target layer 404), as described above with reference to FIG. 4G. In step 1032, a pattern of the patterned mask (e.g., patterned mask 440) is transferred to the target layer (e.g., target layer 404), as described above with reference to FIG. 4H.

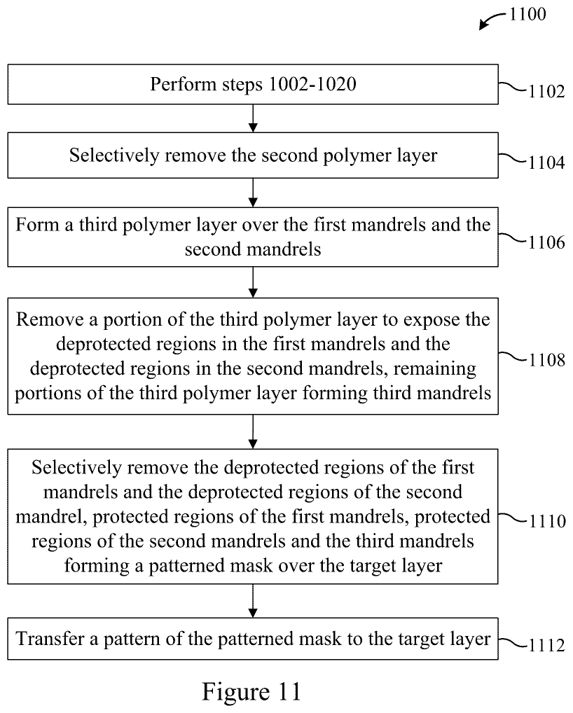

FIG. 11 illustrates a flow diagram of a method 1100 for forming a patterned mask over a substrate in accordance with various embodiments. Method 1100 starts with step 1102. In some embodiments, step 1102 comprises steps 1002-1020 as described above with reference to FIGS. 10A and 10B, and the description is not repeated herein. In step 1104, the second polymer layer (e.g., polymer layer 522) is selectively removed, as described above with reference to FIGS. 5A and 5B. In step 1106, a third polymer layer (e.g., polymer layer 546) is formed over the first mandrels (e.g., mandrels 506) and the second mandrels (e.g., mandrels 518), as described above with reference to FIG. 5C.

In step 1108, a portion of the third polymer layer (e.g., polymer layer 546) is removed to expose the deprotected regions (e.g., deprotected regions 526) of the first mandrels (e.g., mandrels 506) and the deprotected regions (e.g., deprotected regions 530) of the second mandrels (e.g., mandrels 518), such that remaining portions of the third polymer layer (e.g., polymer layer 546) form third mandrels (e.g., mandrels 534), as described above with reference to FIG. 5D. In step 1110, the deprotected regions (e.g., deprotected regions 526) of the first mandrels (e.g., mandrels 506) and the deprotected regions (e.g., deprotected regions 530) of the second mandrels (e.g., mandrels 519) are selectively removed, such that protected regions (e.g., protected regions 528) of the first mandrels (e.g., mandrels 506), protected regions (e.g., protected regions 532) of the second mandrels (e.g., mandrels 518), and the third mandrels (e.g., mandrels 534) form a patterned mask (e.g., patterned mask 540) over the target layer (e.g., target layer 404), as described above with reference to FIG. 5D. In step 1112, a pattern of the patterned mask (e.g., patterned mask 540) is transferred to the target layer (e.g., target layer 504), as described above with reference to FIG. 5E.

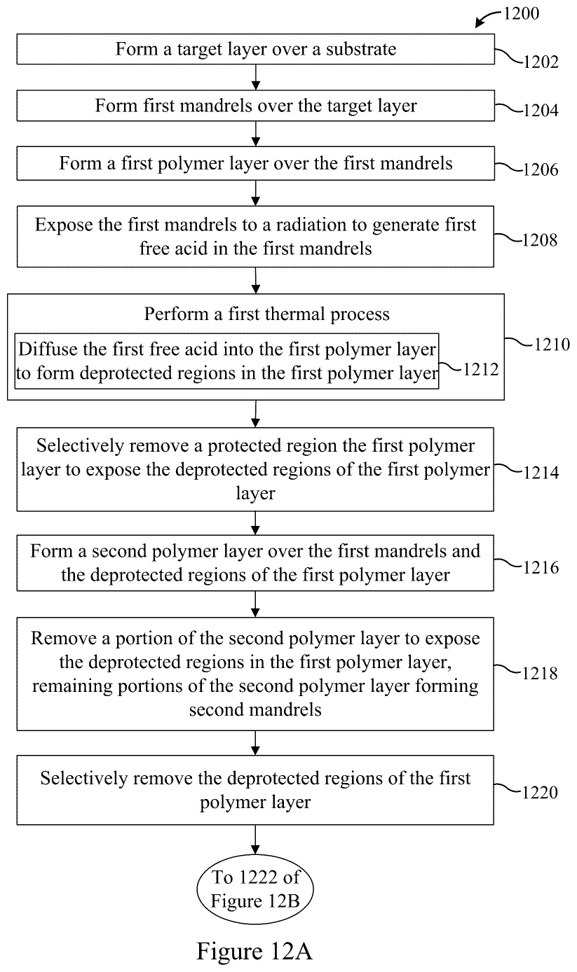

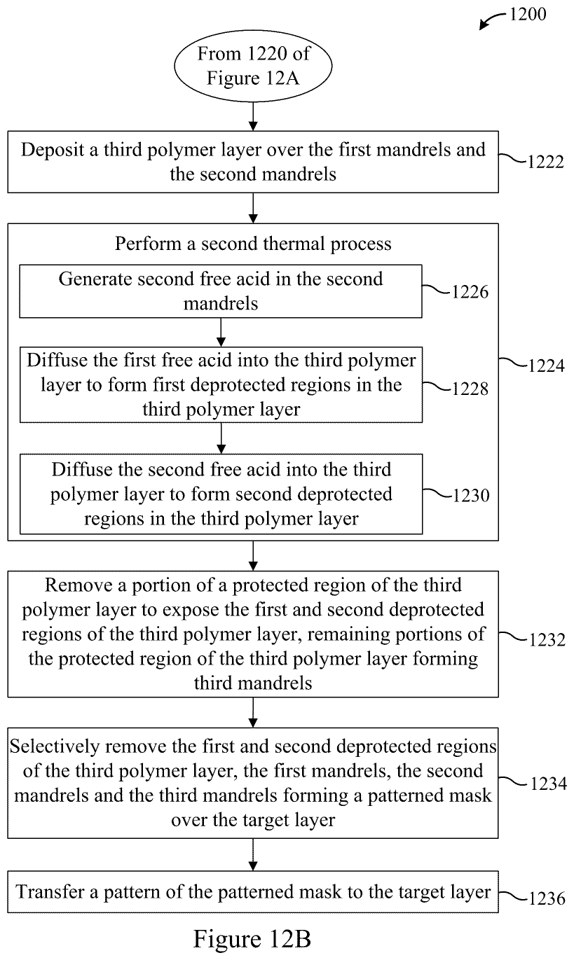

FIGS. 12A and 12B illustrate a flow diagram of a method 1200 for forming a patterned mask over a substrate in accordance with various embodiments. In step 1202, a target layer (e.g., target layer 604) is formed over a substrate (e.g., substrate 602), as described above with reference to FIG. 6A. In step 1204, first mandrels (e.g., mandrels 606) are formed over the target layer (e.g., target layer 604), as described above with reference to FIG. 6A. In step 1206, a first polymer layer (e.g., polymer layer 610) is formed over the first mandrels (e.g., mandrels 606), as described above with reference to FIG. 6B.

In step 1208, the first mandrels (e.g., mandrels 606) are exposed to a radiation (e.g., radiation 612) to generate first free acid (e.g., free acid 614) in the first mandrels (e.g., mandrels 606), as described above with reference to FIG. 6C. In step 1210, a first thermal process is performed, as described above with reference to FIG. 6D. In some embodiments, step 1210 comprises step 1212. In step 1212, the first free acid (e.g., free acid 614) is diffused into the first polymer layer (e.g., polymer layer 610) to form deprotected regions (e.g., deprotected regions 616) in the first polymer layer (e.g., polymer layer 610), as described above with reference to FIG. 6D.

In step 1214, a protected region (e.g., protected regions 618) the first polymer layer (e.g., polymer layer 610) is selectively removed to expose the deprotected regions (e.g., deprotected regions 616) of the first polymer layer (e.g., polymer layer 610), as described above with reference to FIG. 6E. In step 1216, a second polymer layer (e.g., polymer layer 620) is formed over the first mandrels (e.g., mandrels 606) and the deprotected regions (e.g., deprotected regions 616) of the first polymer layer (e.g., polymer layer 610), as described above with reference to FIG. 6F.

In step 1218, a portion of the second polymer layer (e.g., polymer layer 620) is removed to expose the deprotected regions (e.g., deprotected regions 616) of the first polymer layer (e.g., polymer layer 610), such that remaining portions of the second polymer layer (e.g., polymer layer 620) form second mandrels (e.g., mandrels 622), as described above with reference to FIG. 6G. In step 1220, the deprotected regions (e.g., deprotected regions 616) of the first polymer layer (e.g., polymer layer 610) are selectively removed, as described above with reference to FIG. 6G.

In step 1222, a third polymer layer (e.g., polymer layer 626) is formed over the first mandrels (e.g., mandrels 606) and the second mandrels (e.g., mandrels 622), as described above with reference to FIG. 6H. In step 1224, a second thermal process is performed, as described above with reference to FIG. 6I. In some embodiments, step 1224 comprises steps 1226, 1228, and 1230. In step 1226, second free acid (e.g., free acid 628) is generated in the second mandrels (e.g., mandrels 622), as described above with reference to FIG. 6I. In step 1228, the first free acid (e.g., free acid 614) is diffused into the third polymer layer (e.g., polymer layer 626) to form first deprotected regions (e.g., deprotected regions 630) in the third polymer layer (e.g., polymer layer 626), as described above with reference to FIG. 6I. In step 1230, the second free acid (e.g., free acid 628) is diffused into the third polymer layer (e.g., polymer layer 626) to form second deprotected regions (e.g., deprotected regions 632) in the third polymer layer (e.g., polymer layer 626), as described above with reference to FIG. 6I.

In step 1232, a portion of a protected region (e.g., protected region 634) of the third polymer layer (e.g., polymer layer 626) is removed to expose the first deprotected regions (e.g., deprotected regions 630) and the second deprotected regions (e.g., deprotected regions 632) of the third polymer layer (e.g., polymer layer 626), such that remaining portions of the protected region (e.g., protected region 634) of the third polymer layer (e.g., polymer layer 626) form third mandrels (e.g., mandrels 636), as described above with reference to FIG. 6J.

In step 1234, the first deprotected regions (e.g., deprotected regions 630) and the second deprotected regions (e.g., deprotected regions 632) of the third polymer layer (e.g., polymer layer 626) are selectively removed, such that the first mandrels (e.g., mandrels 606), the second mandrels (e.g., mandrels 622), and the third mandrels (e.g., mandrels 636) form a patterned mask (e.g., patterned mask 638) over the target layer (e.g., target layer 604), as described above with reference to FIG. 6J. In step 1236, a pattern of the patterned mask (e.g., patterned mask 638) is transferred to the target layer (e.g., target layer 604), as described above with reference to FIG. 6K.

Example embodiments of the disclosure are described below. Other embodiments can also be understood from the entirety of the specification as well as the claims filed herein.
Example 1. A method including forming first mandrels over a substrate and forming a first polymer layer over the first mandrels. A top surface of the first polymer layer being above top surfaces of the first mandrels. The method further including generating first free acid in the first polymer layer and diffusing the first free acid into the first mandrels to form deprotected regions of the first mandrels. Remaining portions of the first mandrels forming protected regions of the first mandrels. The method further including selectively removing the first polymer layer and forming a second polymer layer over the first mandrels. A top surface of the second polymer layer being above top surfaces of the first mandrels. The method further including removing a portion of the second polymer layer to expose the deprotected regions of the first mandrels. Remaining portions of the second polymer layer forming second mandrels. The method further including selectively removing the deprotected regions of the first mandrels. The protected regions of the first mandrels forming third mandrels. The method further including forming a third polymer layer over the second mandrels and the third mandrels. A top surface of the third polymer layer being above top surfaces of the second mandrels and the third mandrels. The method further including generating second free acid in the third polymer layer and diffusing the second free acid into the second mandrels to form deprotected regions of the second mandrels. Remaining portions of the second mandrels forming protected regions of the second mandrels. The method further including diffusing the second free acid into the third mandrels to form deprotected regions of the third mandrels. Remaining portions of the third mandrels forming protected regions of the third mandrels. The method further including removing a portion of the third polymer layer to expose the deprotected regions of the second mandrels and the deprotected regions of the third mandrels. Remaining portions of the third polymer layer forming fourth mandrels. The method further including selectively removing the deprotected regions of the second mandrels and the deprotected regions of the third mandrels. The protected regions of the second mandrels, the protected regions of the third mandrels, and the fourth mandrels forming a patterned mask.
Example 2. The method of example 1, further including: before forming the first mandrels over the substrate, forming a target layer over the substrate; and after forming the patterned mask, transferring a pattern of the patterned mask to the target layer.
Example 3. The method of any of examples 1 and 2, where generating and diffusing the first free acid includes performing a first thermal process.
Example 4. The method of any of examples 1 to 3, where generating and diffusing the second free acid includes performing a second thermal process.
Example 5. The method of any of examples 1 to 4, where removing the portion of the second polymer layer and selectively removing the deprotected regions of the first mandrels includes dissolving the portion of the second polymer layer and the deprotected regions of the first mandrels using a first solvent.
Example 6. The method of any of examples 1 to 5, where removing the portion of the third polymer layer and selectively removing the deprotected regions of the second mandrels and the deprotected regions of the third mandrels includes dissolving the portion of the third polymer layer, the deprotected regions of the second mandrels and the deprotected regions of the third mandrels using a second solvent.
Example 7. The method of any of examples 1 to 6, where a width of the deprotected regions of the second mandrels is different from a width of the deprotected regions of the third mandrels.
Example 8. A method including: forming first mandrels over a substrate; forming a first polymer layer over the first mandrels, a top surface of the first polymer layer being above top surfaces of the first mandrels; generating first free acid in the first polymer layer; diffusing the first free acid into the first mandrels to form deprotected regions of the first mandrels, where remaining portions of the first mandrels form protected regions of the first mandrels; selectively removing the first polymer layer; forming a second polymer layer over the first mandrels, a top surface of the second polymer layer being above top surfaces of the first mandrels; removing a portion of the second polymer layer to expose the deprotected regions of the first mandrels, where remaining portions of the second polymer layer form second mandrels; selectively removing the deprotected regions of the first mandrels, where the protected regions of the first mandrels form third mandrels; forming a third polymer layer over the second mandrels and the third mandrels, a top surface of the third polymer layer being above top surfaces of the second mandrels and the third mandrels; generating second free acid in the second mandrels and third free acid in the third mandrels; diffusing the second free acid into the third polymer layer to form first deprotected regions of the third polymer layer; diffusing the third free acid into the third polymer layer to form second deprotected regions of the third polymer layer, where a remaining portion of the third polymer layer forms a protected region of the third polymer layer; removing a portion of the protected region of the third polymer layer to expose the first deprotected regions and the second deprotected regions of the third polymer layer, where remaining portions of the protected region of the third polymer layer form fourth mandrels; and selectively removing the first deprotected regions and the second deprotected regions of the third polymer layer, where the second mandrels, the third mandrels, and the fourth mandrels form a patterned mask.
Example 9. The method of example 8, further including: before forming the first mandrels over the substrate, forming a target layer over the substrate; and after forming the patterned mask, transferring a pattern of the patterned mask to the target layer.
Example 10. The method of any of examples 8 and 9, where generating and diffusing the first free acid includes performing a first thermal process.
Example 11. The method of any of examples 8 to 10, where generating the second free acid and the third free acid in the third mandrels includes exposing the second mandrels and the third mandrels to a radiation.
Example 12. The method of any of examples 8 to 11, where diffusing the second free acid and the third free acid includes performing a second thermal process.
Example 13. The method of any of examples 8 to 12, where removing the portion of the second polymer layer and selectively removing the deprotected regions of the first mandrels includes dissolving the portion of the second polymer layer and the deprotected regions of the first mandrels using a first solvent.
Example 14. The method of any of examples 8 to 13, where removing the portion of the protected region of the third polymer layer and selectively removing the first deprotected regions and the second deprotected regions of the third polymer layer includes dissolving the portion of the protected region of the third polymer layer and the first deprotected regions and the second deprotected regions of the third polymer layer using a second solvent.
Example 15. A method including: forming first mandrels over a substrate; forming a first polymer layer over the first mandrels, a top surface of the first polymer layer being above top surfaces of the first mandrels; generating first free acid in the first mandrels; diffusing the first free acid into the first polymer layer to form deprotected regions of the first polymer layer, where a remaining portion of the first polymer layer forms a protected region of the first polymer layer; removing a portion of the protected region of the first polymer layer to exposed the deprotected regions of the first polymer layer, where remaining portions of the protected region of the first polymer layer form second mandrels; selectively removing the protected regions of the first polymer layer; forming a second polymer layer over the first mandrels and the second mandrels, a top surface of the second polymer layer being above top surfaces of the first mandrels and the second mandrels; generating second free acid in the second polymer layer; diffusing the second free acid into the first mandrels to form deprotected regions of the first mandrels, where remaining portions of the first mandrels form protected regions of the first mandrels; diffusing the second free acid into the second mandrels to form deprotected regions of the second mandrels, where remaining portions of the second mandrels form protected regions of the second mandrels; removing a portion of the second polymer layer to expose the deprotected regions of the first mandrels and the deprotected regions of the second mandrels, where remaining portions of the second polymer layer form third mandrels; and selectively removing the deprotected regions of the first mandrels and the deprotected regions of the second mandrels, where the protected regions of the first mandrels, the protected regions of the second mandrels, and the third mandrels form a patterned mask.
Example 16. The method of example 15, further including: before forming the first mandrels over the substrate, forming a target layer over the substrate; and after forming the patterned mask, transferring a pattern of the patterned mask to the target layer.
Example 17. The method of any of examples 15 and 16, where generating and diffusing the first free acid includes performing a first thermal process.
Example 18. The method of any of examples 15 to 17, where generating and diffusing the second free acid includes performing a second thermal process.
Example 19. The method of any of examples 15 to 18, where removing the portion of the protected region of the first polymer layer and selectively removing the deprotected regions of the first polymer layer includes dissolving the portion of the protected region of the first polymer layer and the deprotected regions of the first polymer layer using a first solvent.
Example 20. The method of any of examples 15 to 19, where removing the portion of the second polymer layer and selectively removing the deprotected regions of the first mandrels and the deprotected regions of the second mandrels includes dissolving the portion of the second polymer layer, the deprotected regions of the first mandrels and the deprotected regions of the second mandrels using a second solvent.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways.

“Substrate,” “target substrate,” “structure,” or “device” as used herein generically refers to an object being processed in accordance with the disclosure, and may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate, structure, or device is not limited to any particular base structure, underlying layer or overlying layer, patterned or un-patterned, but rather, is contemplated to include any such layer or base structure, and any combination of layers and/or base structures. The description may reference particular types of substrates, structures, or devices, but this is for illustrative purposes only.

Although this disclosure describes particular process steps as occurring in a particular order, this disclosure contemplates the process steps occurring in any suitable order. While this disclosure has been described with reference to illustrative embodiments, this description is not intended to be construed in a limiting sense. Various modifications and combinations of the illustrative embodiments, as well as other embodiments of the disclosure, will be apparent to persons skilled in the art upon reference to the description. It is therefore intended that the appended claims encompass any such modifications or embodiments.

What is claimed is:

1. A method comprising:
forming first mandrels over a substrate;
forming a first polymer layer over the first mandrels, a top surface of the first polymer layer being above top surfaces of the first mandrels;
generating first free acid in the first polymer layer;
diffusing the first free acid into the first mandrels to form deprotected regions of the first mandrels, wherein remaining portions of the first mandrels form protected regions of the first mandrels;
selectively removing the first polymer layer;
forming a second polymer layer over the first mandrels, a top surface of the second polymer layer being above top surfaces of the first mandrels;
removing a portion of the second polymer layer to expose the deprotected regions of the first mandrels, wherein remaining portions of the second polymer layer form second mandrels;
selectively removing the deprotected regions of the first mandrels, wherein the protected regions of the first mandrels form third mandrels;
forming a third polymer layer over the second mandrels and the third mandrels, a top surface of the third polymer layer being above top surfaces of the second mandrels and the third mandrels;
generating second free acid in the third polymer layer;
diffusing the second free acid into the second mandrels to form deprotected regions of the second mandrels, wherein remaining portions of the second mandrels form protected regions of the second mandrels;
diffusing the second free acid into the third mandrels to form deprotected regions of the third mandrels, wherein remaining portions of the third mandrels form protected regions of the third mandrels;
removing a portion of the third polymer layer to expose the deprotected regions of the second mandrels and the deprotected regions of the third mandrels, wherein remaining portions of the third polymer layer form fourth mandrels; and
selectively removing the deprotected regions of the second mandrels and the deprotected regions of the third mandrels, wherein the protected regions of the second mandrels, the protected regions of the third mandrels, and the fourth mandrels form a patterned mask.

2. The method of claim 1, further comprising:
before forming the first mandrels over the substrate, forming a target layer over the substrate; and
after forming the patterned mask, transferring a pattern of the patterned mask to the target layer.

3. The method of claim 1, wherein generating and diffusing the first free acid comprises performing a first thermal process.

4. The method of claim 1, wherein generating and diffusing the second free acid comprises performing a second thermal process.

5. The method of claim 1, wherein removing the portion of the second polymer layer and selectively removing the deprotected regions of the first mandrels comprises dissolving the portion of the second polymer layer and the deprotected regions of the first mandrels using a first solvent.

6. The method of claim 1, wherein removing the portion of the third polymer layer and selectively removing the deprotected regions of the second mandrels and the deprotected regions of the third mandrels comprises dissolving the portion of the third polymer layer, the deprotected regions of the second mandrels and the deprotected regions of the third mandrels using a second solvent.

7. The method of claim 1, wherein a width of the deprotected regions of the second mandrels is different from a width of the deprotected regions of the third mandrels.

8. A method comprising:
forming first mandrels over a substrate;
forming a first polymer layer over the first mandrels, a top surface of the first polymer layer being above top surfaces of the first mandrels;
generating first free acid in the first polymer layer;
diffusing the first free acid into the first mandrels to form deprotected regions of the first mandrels, wherein remaining portions of the first mandrels form protected regions of the first mandrels;
selectively removing the first polymer layer;
forming a second polymer layer over the first mandrels, a top surface of the second polymer layer being above top surfaces of the first mandrels;
removing a portion of the second polymer layer to expose the deprotected regions of the first mandrels, wherein remaining portions of the second polymer layer form second mandrels;
selectively removing the deprotected regions of the first mandrels, wherein the protected regions of the first mandrels form third mandrels;
forming a third polymer layer over the second mandrels and the third mandrels, a top surface of the third polymer layer being above top surfaces of the second mandrels and the third mandrels;
generating second free acid in the second mandrels and third free acid in the third mandrels;
diffusing the second free acid into the third polymer layer to form first deprotected regions of the third polymer layer;
diffusing the third free acid into the third polymer layer to form second deprotected regions of the third polymer layer, wherein a remaining portion of the third polymer layer forms a protected region of the third polymer layer;
removing a portion of the protected region of the third polymer layer to expose the first deprotected regions and the second deprotected regions of the third polymer layer, wherein remaining portions of the protected region of the third polymer layer form fourth mandrels; and
selectively removing the first deprotected regions and the second deprotected regions of the third polymer layer, wherein the second mandrels, the third mandrels, and the fourth mandrels form a patterned mask.

9. The method of claim 8, further comprising:
before forming the first mandrels over the substrate, forming a target layer over the substrate; and
after forming the patterned mask, transferring a pattern of the patterned mask to the target layer.

10. The method of claim 8, wherein generating and diffusing the first free acid comprises performing a first thermal process.

11. The method of claim 8, wherein generating the second free acid and the third free acid in the third mandrels comprises exposing the second mandrels and the third mandrels to a radiation.

12. The method of claim 8, wherein diffusing the second free acid and the third free acid comprises performing a second thermal process.

13. The method of claim 8, wherein removing the portion of the second polymer layer and selectively removing the deprotected regions of the first mandrels comprises dissolving the portion of the second polymer layer and the deprotected regions of the first mandrels using a first solvent.

14. The method of claim 8, wherein removing the portion of the protected region of the third polymer layer and selectively removing the first deprotected regions and the second deprotected regions of the third polymer layer comprises dissolving the portion of the protected region of the third polymer layer and the first deprotected regions and the second deprotected regions of the third polymer layer using a second solvent.

15. A method comprising:
forming first mandrels over a substrate;
forming a first polymer layer over the first mandrels, a top surface of the first polymer layer being above top surfaces of the first mandrels;
generating first free acid in the first mandrels;
diffusing the first free acid into the first polymer layer to form deprotected regions of the first polymer layer, wherein a remaining portion of the first polymer layer forms a protected region of the first polymer layer;
removing a portion of the protected region of the first polymer layer to exposed the deprotected regions of the first polymer layer, wherein remaining portions of the protected region of the first polymer layer form second mandrels;
selectively removing the protected regions of the first polymer layer;
forming a second polymer layer over the first mandrels and the second mandrels, a top surface of the second polymer layer being above top surfaces of the first mandrels and the second mandrels;
generating second free acid in the second polymer layer;
diffusing the second free acid into the first mandrels to form deprotected regions of the first mandrels, wherein remaining portions of the first mandrels form protected regions of the first mandrels;
diffusing the second free acid into the second mandrels to form deprotected regions of the second mandrels, wherein remaining portions of the second mandrels form protected regions of the second mandrels;
removing a portion of the second polymer layer to expose the deprotected regions of the first mandrels and the deprotected regions of the second mandrels, wherein remaining portions of the second polymer layer form third mandrels; and
selectively removing the deprotected regions of the first mandrels and the deprotected regions of the second mandrels, wherein the protected regions of the first mandrels, the protected regions of the second mandrels, and the third mandrels form a patterned mask.

16. The method of claim 15, further comprising:
before forming the first mandrels over the substrate, forming a target layer over the substrate; and
after forming the patterned mask, transferring a pattern of the patterned mask to the target layer.

17. The method of claim 15, wherein generating and diffusing the first free acid comprises performing a first thermal process.

18. The method of claim 15, wherein generating and diffusing the second free acid comprises performing a second thermal process.

19. The method of claim 15, wherein removing the portion of the protected region of the first polymer layer and selectively removing the deprotected regions of the first polymer layer comprises dissolving the portion of the protected region of the first polymer layer and the deprotected regions of the first polymer layer using a first solvent.

20. The method of claim 15, wherein removing the portion of the second polymer layer and selectively removing the deprotected regions of the first mandrels and the deprotected regions of the second mandrels comprises dissolving the portion of the second polymer layer, the deprotected regions of the first mandrels and the deprotected regions of the second mandrels using a second solvent.
